(19) United States
(12) Patent Application Publication
(10) Pub. No.: US 2021/0210691 A1
(43) Pub. Date: Jul. 8, 2021

(54) POLYMERIC LAYER AND ORGANIC ELECTRONIC DEVICE COMPRISING SAME.

(71) Applicants: Dow Global Technologies LLC, Midland, MI (US); Rohm and Haas Electronic Materials LLC, Marlborough, MA (US); Rohm and Haas Electronic Materials Korea Ltd., Cheonan (KR)

(72) Inventors: Minrong Zhu, Shanghai (CN); Jichang Feng, Shanghai (CN); Jing Jing Yan, Shanghai (CN); Zhengming Tang, Shanghai (CN); Shaoguang Feng, Shanghai (CN); Hua Ren, Shanghai (CN); Hong Yeop Na, Hwaseong (KR); Yoo-Jin Doh, Gwacheon (KR); Yuchen Liu, Shanghai (CN); David D. Devore, Midland, MI (US); Peter Trefonas, III, Medway, MA (US); Liam P. Spencer, Manvel, TX (US)

(21) Appl. No.: 16/065,291

(22) PCT Filed: Dec. 24, 2015
(86) PCT No.: PCT/CN2015/098610

§ 371 Date: Jun. 22, 2018

(51) Int. Cl. H01L 51/00; C08F 112/32; C08K 5/55

(52) U.S. Cl. CPC H01L 51/0039; C08F 112/32; H01L 51/506; H01L 51/0043; C08K 2201/001; C08K 5/55

(57) ABSTRACT

Polymeric layers suitable for organic layers of electronic devices that show reduced driving voltage and/or increased luminous efficiency.

### FIELD OF THE INVENTION

The present invention relates to a polymeric layer and an organic electronic device comprising the polymeric layer.

### INTRODUCTION

Organic electronic devices are endowed with advantages such as flexibility, low power consumption, and relatively low cost over conventional inorganic electronic devices. Organic electronic devices usually include organic light emitting devices such as an organic light emitting diode (OLED). OLEDs have a multi-layer structure and typically include an anode and a metal cathode. Sandwiched between the anode and the metal cathode are organic layers such as a hole injection layer (HIL), a hole transport layer (HTL), an emitting material layer (EML), an electron transport layer (ETL) or an electron injection layer (EIL).

Key properties for materials for these organic layers include long lifetime, reduced driving voltage and/or increased luminous efficiency to minimize power consumption in OLED displays, especially for mobile applications where batteries are used as power sources. In the case of HTL layer, the process by which the layer is deposited is also critical for its end-use application.

Methods for depositing HTL layer, in small display applications, usually involve evaporation of a small organic compound with a fine metal mask to direct the deposition. In the case of large displays, this approach is not practical from a material usage and high throughput perspective.

One approach that appears promising is a solution process which involves the deposition of a small molecule HTL material attached with crosslinking or polymerization moieties. Solution process based methods include spin-coating, inkjet printing, and screen printing which are well-known in the art. However, these approaches have their own shortcomings. In particular, the mobility of the charges in the HTL becomes reduced, as a result of crosslinking or polymerization chemistry. This reduced hole mobility leads to poor properties such as device lifetime and even luminous efficiency.

Therefore it is desirable to provide materials for use in organic layers that have improved properties and, when used in a HTL layer, are amenable to solution-based deposition while maintaining improved properties.

### SUMMARY OF THE INVENTION

The present invention provides a polymeric layer, a process of preparing the polymeric layer, and an organic electronic device comprising the polymeric layer. The organic electronic device demonstrates improved properties including, for example, higher efficiency and lower driving voltage than an organic electronic device comprising a layer of N,N′-bis(naphthalen-1-yl)-N,N′-bis(phenyl)benzidine (NPB).

In a first aspect, the present invention provides a polymeric layer formed by a composition comprising,

(a) from 1% to 20% by weight of a p-dopant, based on the total weight of the composition, wherein the p-dopant is selected from trityl salts, ammonium salts, iodonium salts, tropylium salts, imidazolium salts, phosphonium salts, oxonium salts, or mixtures thereof; and

(b) one or more monomers comprising, based on the total moles of the monomers in the composition, from 54% to 100% by mole of Monomer B; wherein Monomer B has the structure represented by Structure B:

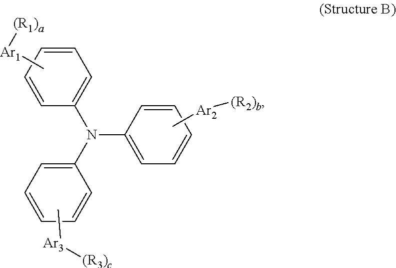

Ar₁, Ar₂ and Ar₃ are each independently selected from a C₆-C₆₀ substituted arylene, a C₆-C₆₀ arylene, a C₄-C₆₀ substituted heteroarylene, or a C₄-C₆₀ heteroarylene; Ar₁, Ar₂ and Ar₃ may each independently form a ring structure with the adjacent phenyl group they are bonded to;

(R₁)ₐ, (R₂)_{b} and (R₃)_{c} are each independently selected from hydrogen, a C₁-C₆₀ hydrocarbyl, a C₁-C₆₀ substituted hydrocarbyl, a halogen, a cyano, a nitro, a C₁-C₆₀ alkoxy, or a hydroxyl; with the proviso that two or more of (R₁)ₐ, (R₂)_{b} and (R₃)_{c} independently have the following Structure D:

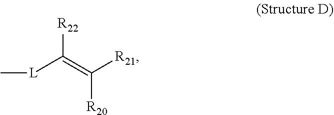

wherein L is selected from a covalent bond, a heteroatom, an aromatic moiety, a heteroaromatic moiety, a C₁-C₁₀₀ hydrocarbyl, a C₁-C₁₀₀ substituted hydrocarbyl, a C₁-C₁₀₀ heterohydrocarbyl, or a C₁-C₁₀₀ substituted heterohydrocarbyl; and

wherein R₂₀ through R₂₂ are each independently selected from hydrogen, deuterium, a C₁-C₅₀ hydrocarbyl, a C₁-C₅₀ substituted hydrocarbyl, a C₁-C₅₀ heterohydrocarbyl, a C₁-C₅₀ substituted heterohydrocarbyl, a halogen, a cyano, a C₆-C₅₀ aryl, a C₆-C₅₀ substituted aryl, a C₄-C₅₀ heteroaryl, or a C₄-C₅₀ substituted heteroaryl.

In a second aspect, the present invention is a method of making a polymeric layer of the first aspect. The method comprises:

(i) providing a composition comprising,

(a) from 1% to 20% by weight of a p-dopant, based on the total weight of the composition, wherein the p-dopant is selected from trityl salts, ammonium salts, iodonium salts, tropylium salts, imidazolium salts, phosphonium salts, oxonium salts, or mixtures thereof; and

(b) one or more monomers comprising, based on the total moles of the monomers in the composition, from 54% to 100% by mole of Monomer B; wherein Monomer B has the structure represented by Structure B:

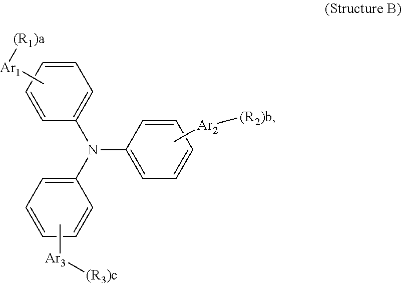

Ar₁, Ar₂ and Ar₃ are each independently selected from a C₆-C₆₀ substituted arylene, a C₆-C₆₀ arylene, a C₄-C₆₀ substituted heteroarylene, or a C₄-C₆₀ heteroarylene; Ar₁, Ar₂ and Ar₃ may each independently form a ring structure with the adjacent phenyl group they are bonded to;

(R₁)ₐ, (R₂)_{b} and (R₃)_{c} are each independently selected from hydrogen, a C₁-C₆₀ hydrocarbyl, a C₁-C₆₀ substituted hydrocarbyl, a halogen, a cyano, a nitro, a C₁-C₆₀ alkoxy, or a hydroxyl; with the proviso that two or more of (R₁)ₐ, (R₂)_{b} and (R₃)_{c} independently have the following Structure D:

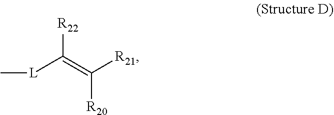

wherein L is selected from a covalent bond, a heteroatom, an aromatic moiety, a heteroaromatic moiety, a C₁-C₁₀₀ hydrocarbyl, a C₁-C₁₀₀ substituted hydrocarbyl, a C₁-C₁₀₀ heterohydrocarbyl, or a C₁-C₁₀₀ substituted heterohydrocarbyl; and

wherein R₂₀ through R₂₂ are each independently selected from hydrogen, deuterium, a C₁-C₅₀ hydrocarbyl, a C₁-C₅₀ substituted hydrocarbyl, a C₁-C₅₀ heterohydrocarbyl, a C₁-C₅₀ substituted heterohydrocarbyl, a halogen, a cyano, a C₆-C₅₀ aryl, a C₆-C₅₀ substituted aryl, a C₄-C₅₀ heteroaryl, or a C₄-C₅₀ substituted heteroaryl;

(ii) dissolving or dispersing the composition in one or more organic solvents to obtain a crosslinkable solution;

(iii) depositing the crosslinkable solution to a substrate; and

(iv) crosslinking and drying the crosslinkable solution to form the polymeric layer.

In a third aspect, the present invention provides an electronic device comprising a polymeric layer of the first aspect.

### DETAILED DESCRIPTION OF THE INVENTION

The polymeric layer of the present invention is formed by a composition, preferably formed by crosslinking the composition. The composition useful in the present invention comprises one or more monomers comprising Monomer B. The monomers in the composition comprises, based on the total moles of the monomers in the composition, from 54% by mole to 100% by mole of Monomer B.

Monomer B useful in the present invention may have the structure represented by Structure B:

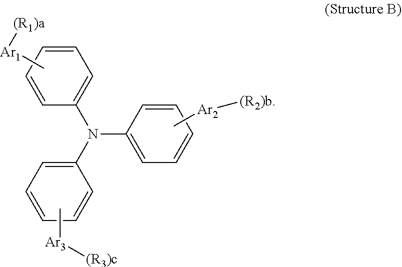

Preferably, two of groups (R₁)ₐ, (R₂)_{b} and (R₃)_{c} have the structure represented by Structure D, where the polymer obtained therefrom has a crosslinked structure.

L in Structure D useful in the present invention may be selected from the group consisting of a covalent bond; —O—; -alkylene-; -arylene-; -alkylene-arylene-; -arylene-alkylene-; —O-alkylene-; —O-arylene-; —O-alkylene-arylene-; —O-alkylene-O—; —O-alkylene-O-alkylene-O—; —O-arylene-O—; —O-alkylene-arylene-O—; —O—(CH₂CH₂—O)n-, wherein n is from 2 to 20; —O-alkylene-O-alkylene-; —O-alkylene-O-arylene-; —O-arylene-O—; —O-arylene-O-alkyene-; —O-arylene-O-arylene. Preferably, L is selected from -alkylene-, -arylene-, -alkylene-arylene-, -arylene-alkylene-, or a covalent bond. More preferably, L is selected from -arylene-, -arylene-alkylene-, or a covalent bond.

Preferably, Structure D useful in the present invention is selected from the following structure:

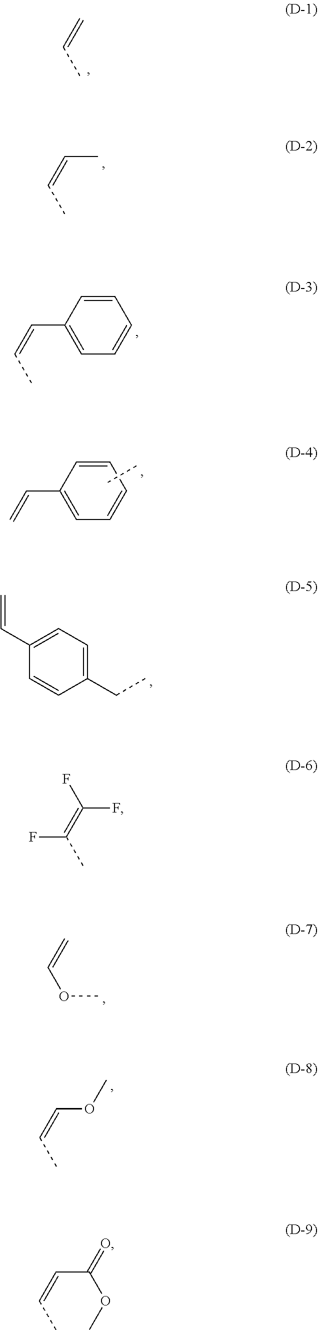

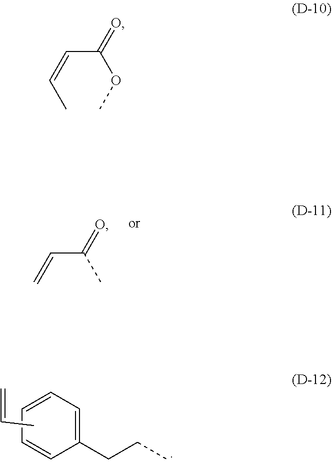

More preferably, Structure D is selected from D-1, D-4, D-5, D-11, or D-12.

The composition of the present invention may comprise a mixture of two or more types of Monomer B all having the structure represented by Structure B.

In some embodiments, Monomer B useful in the present invention has the structure represented by Structure B-I:

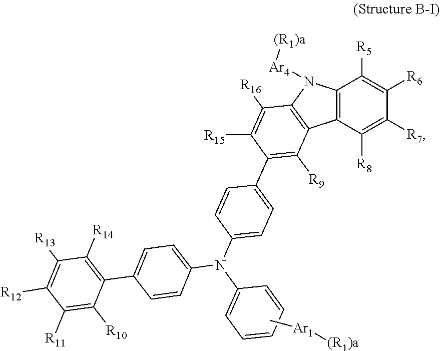

wherein R₅ through R₁₆ are each independently selected from hydrogen, a C₁-C₆₀ hydrocarbyl, a C₄-C₄₀ hydrocarbyl, a C₆-C₃₀ hydrocarbyl, or a C₅-C₂₅ hydrocarbyl; a C₁-C₆₀ substituted hydrocarbyl, a C₄-C₄₀ substituted hydrocarbyl, a C₆-C₃₀ substituted hydrocarbyl, or a C₈-C₂₅ substituted hydrocarbyl; a halogen including, for example, fluoride, chloride, or bromide; a cyano; a nitro; a C₁-C₆₀ alkoxy, a C₂-C₄₀ alkoxy, a C₄-C₃₀ alkoxy, or a C₆-C₂₀ alkoxy; or a hydroxyl;

wherein one of R₁₀ through R₁₄ is (R₂)_{b};

wherein (R₁)ₐ, (R₂)_{b} and (R₄)_{d} are each independently selected from hydrogen, a C₁-C₆₀ hydrocarbyl, a C₄-C₄₀ hydrocarbyl, a C₆-C₃₀ hydrocarbyl, or a C₈-C₂₅ hydrocarbyl; a C₁-C₆₀ substituted hydrocarbyl, a C₄-C₄₀ substituted hydrocarbyl, a C₆-C₃₀ substituted hydrocarbyl, or a C₈-C₂₅ substituted hydrocarbyl; a halogen including, for example, fluoride, chloride, or bromide; a cyano; a nitro; a C₁-C₆₀ alkoxy, a C₄-C₄₀ alkoxy, a C₆-C₃₀ alkoxy, or a C₈-C₂₅ alkoxy; or a hydroxyl;

with the proviso that two or more of (R₁)ₐ, (R₂)_{b} and (R₄)_{d}, R₅ through R₁₆ have the structure represented by Structure D as previously described;

wherein Ar₁ and Ar₄ are each independently selected from a C₆-C₆₀ substituted arylene, a C₆-C₅₀ substituted arylene, a C₆-C₄₀ substituted arylene, or a C₆-C₃₀ substituted arylene; a C₆-C₆₀ arylene, a C₆-C₅₀ arylene, a C₆-C₄₀ arylene, or a C₆-C₃₀ arylene; a C₄-C₆₀ substituted heteroarylene, a C₄-C₅₀ substituted heteroarylene, a C₄-C₄₀ substituted heteroarylene, or a C₄-C₃₀ substituted heteroarylene; or a C₄-C₆₀ heteroarylene, a C₄-C₅₀ heteroarylene, a C₄-C₄₀ heteroarylene, or a C₄-C₃₀ heteroarylene; and

wherein one or more hydrogen atoms may be optionally substituted with deuterium.

Preferably, for Structure B-I, R₈ through R₁₆ are each hydrogen.

The composition of the present invention may comprise a mixture of two or more types of Monomer B all having the structure represented by Structure B-I.

In some other embodiments, Monomer B has the structure represented by Structure B-II:

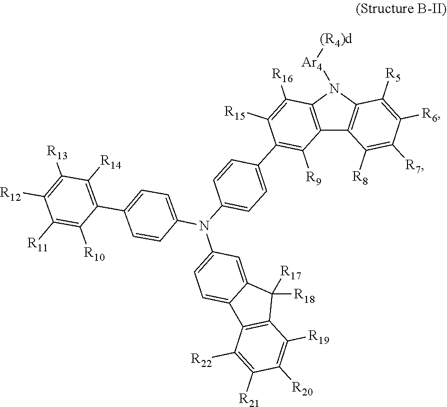

wherein R₅ through R₂₂ are each independently selected from hydrogen, a C₁-C₆₀ hydrocarbyl, a C₄-C₄₀ hydrocarbyl, a C₆-C₃₀ hydrocarbyl, or a C₈-C₂₅ hydrocarbyl; a C₁-C₆₀ substituted hydrocarbyl, a C₄-C₄₀ substituted hydrocarbyl, a C₆-C₃₀ substituted hydrocarbyl, or a C₈-C₂₅ substituted hydrocarbyl; a halogen including, for example, fluoride, chloride, or bromide; a cyano; a nitro; a C₁-C₆₀ alkoxy, a C₂-C₄₀ alkoxy, a C₄-C₃₀ alkoxy, or a C₆-C₂₀ alkoxy; or a hydroxyl;

wherein one of R₁₇ through R₂₂ is (R₁)a;

wherein one of R₁₀ through R₁₄ is (R₂)_{b};

wherein (R₁)ₐ, (R₂)_{b}, (R₄)_{d} and Ar₄ are each as previously described in Structure B-I; with the proviso that two or more of (R₁)ₐ, (R₂)_{b}, (R₄)_{d}, and R₅ through R₂₂ independently have the structure represented by Structure D as previously described; and

wherein one or more hydrogen atoms may be optionally substituted with deuterium.

Preferably, for Structure B-II, R₈ through R₂₂ are each hydrogen.

The composition of the present invention may comprise a mixture of two or more types of Monomer B all having the structure represented by Structure B-II.

In some other embodiments, Monomer B has the structure represented by Structure B-III:

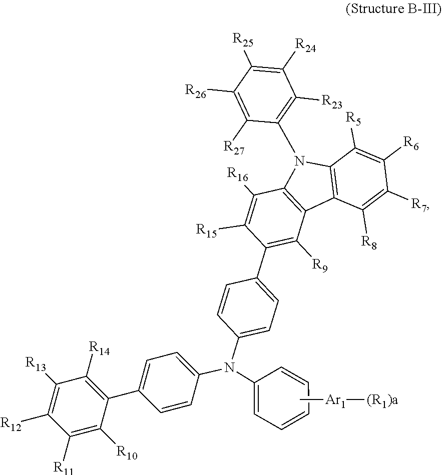

wherein R₅ through R₁₆ and R₂₃ through R₂₇ are each independently selected from hydrogen, a C₁-C₆₀ hydrocarbyl, a C₄-C₄₀ hydrocarbyl, a C₆-C₃₀ hydrocarbyl, or a C₈-C₂₅ hydrocarbyl; a C₁-C₆₀ substituted hydrocarbyl, a C₄-C₄₀ substituted hydrocarbyl, a C₆-C₃₀ substituted hydrocarbyl, or a C₈-C₂₅ substituted hydrocarbyl; a halogen including, for example, fluoride, chloride, or bromide; a cyano; a nitro; a C₁-C₆₀ alkoxy, a C₂-C₄₀ alkoxy, a C₄-C₃₀ alkoxy, or a C₆-C₂₀ alkoxy; or a hydroxyl;

wherein one of R₁₀ through R₁₄ is (R₂)_{b};

wherein one of R₂₃ through R₂₇ is (R₄)_{d};

wherein (R₁)ₐ, (R₂)_{b}, (R₄)_{d} and Ar₁ are each as previously described in Structure B-I; with the proviso that two or more of groups (R₁)a, (R₂)_{b}, (R₄)_{d}, R₅ through R₁₆ and R₂₃ through R₂₇ independently have the structure represented by Structure D as previously described; and

wherein one or more hydrogen atoms may be optionally substituted with deuterium.

Preferably, for Structure B-III, R₈ through R₁₆ are each hydrogen.

The composition of the present invention may comprise a mixture of two or more types of Monomer B all having the structure represented by Structure B-III.

In some embodiments, the composition of the present invention may comprise a mixture of one or more types of Monomer B having the structure represented by Structure B, Structure B-I, Structure B-II, or Structure B-III.

Ar₁, Ar₂ and Ar₃ in Structure B; Ar₁ and Ar₄ in Structure B-I; Ar₄ in Structure B-II; and Ar₁ in Structure B-III may be each independently selected from Ar₁₋₁ through Ar₁₋₇:

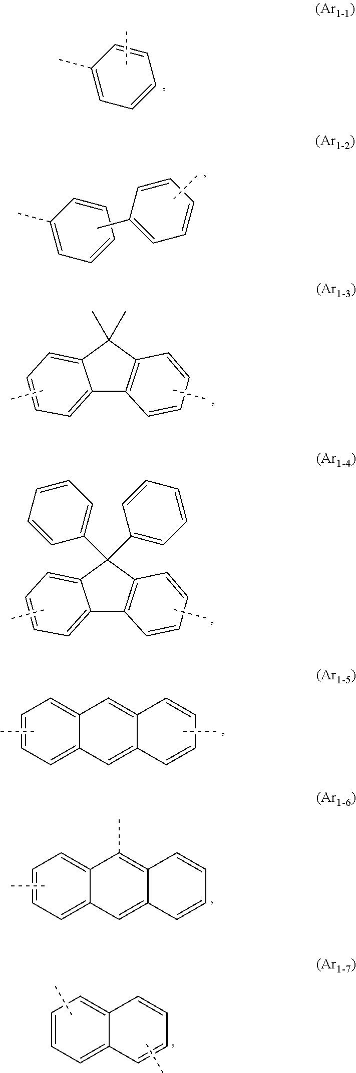

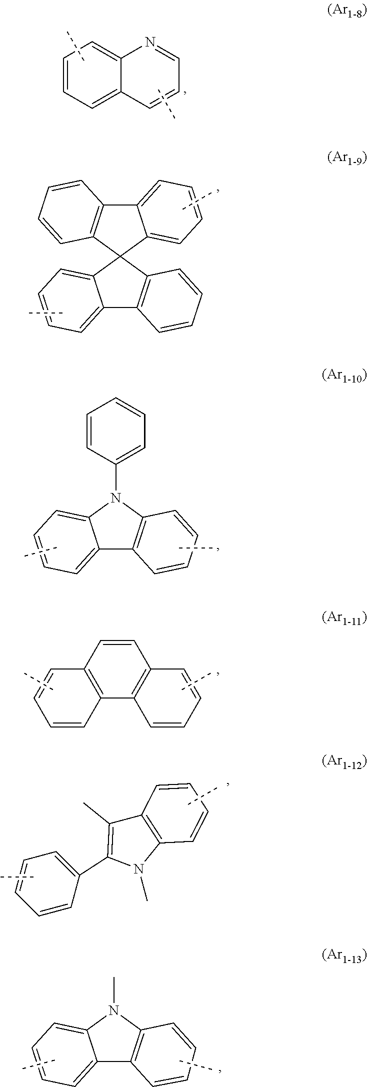

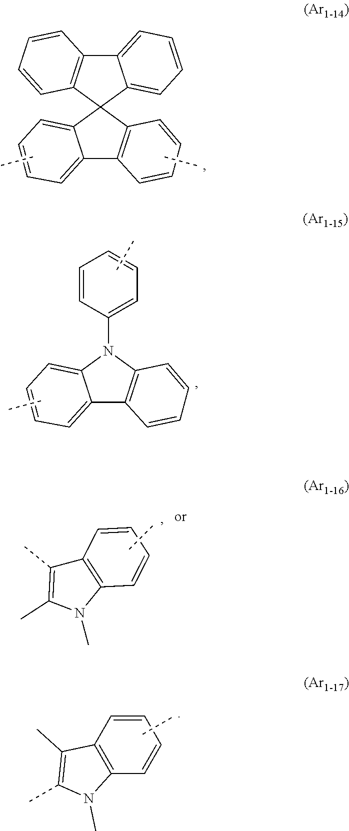

Preferably, Ar₁, Ar₂ and Ar₃ in Structure B; Ar₁ and Ar₄ in Structure B-I; Ar₄ in Structure B-II and Ar₁ in Structure B-III are each independently selected from Ar₁₋₁, Ar₁₋₂, Ar₁₋₃, Ar₁₋₄, Ar₁₋₇, Ar₁₋₉, Ar₁₋₁₀, Ar₁₋₁₃, Ar₁₋₁₅, or Ar₁₋₁₇.

Monomer B useful in the present invention may be selected from one or more of the following compounds (B1) through (B16):

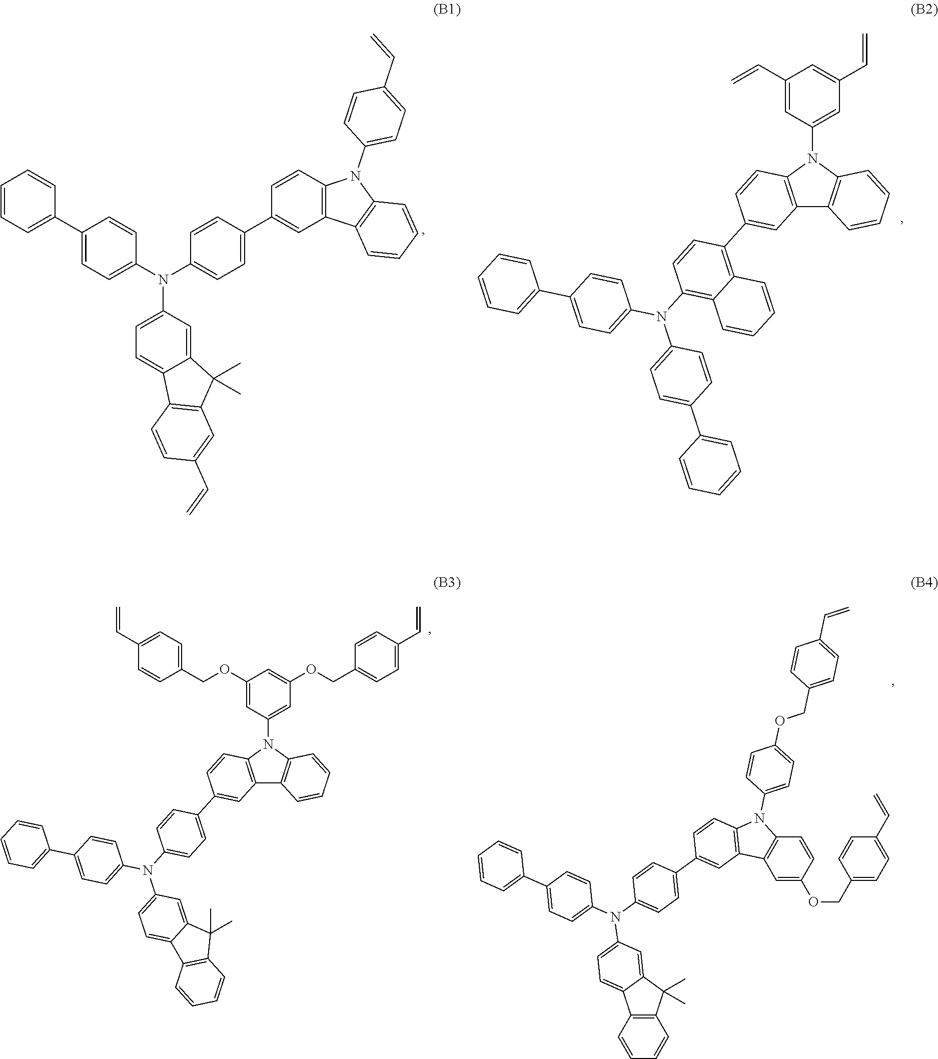 [SMILES: C=Cc1ccc(-n2c3ccccc3c3cc(-c4ccc(N(c5ccc(-c6ccccc6)cc5)c5ccc6c(c5)C(C)(C)c5cc(C=C)ccc5-6)cc4)ccc32)cc1 ; C=Cc1cc(C=C)cc(-n2c3ccccc3c3cc(-c4ccc(N(c5ccc(-c6ccccc6)cc5)c5ccc(-c6ccccc6)cc5)c5ccccc45)ccc32)c1 ; C=Cc1ccc(COc2cc(OCc3ccc(C=C)cc3)cc(-n3c4ccccc4c4cc(-c5ccc(N(c6ccc(-c7ccccc7)cc6)c6ccc7c(c6)C(C)(C)c6ccccc6-7)cc5)ccc43)c2)cc1 ; C=Cc1ccc(COc2ccc(-n3c4ccc(OCc5ccc(C=C)cc5)cc4c4cc(-c5ccc(N(c6ccc(-c7ccccc7)cc6)c6ccc7c(c6)C(C)(C)c6ccccc6-7)cc5)ccc43)cc2)cc1]

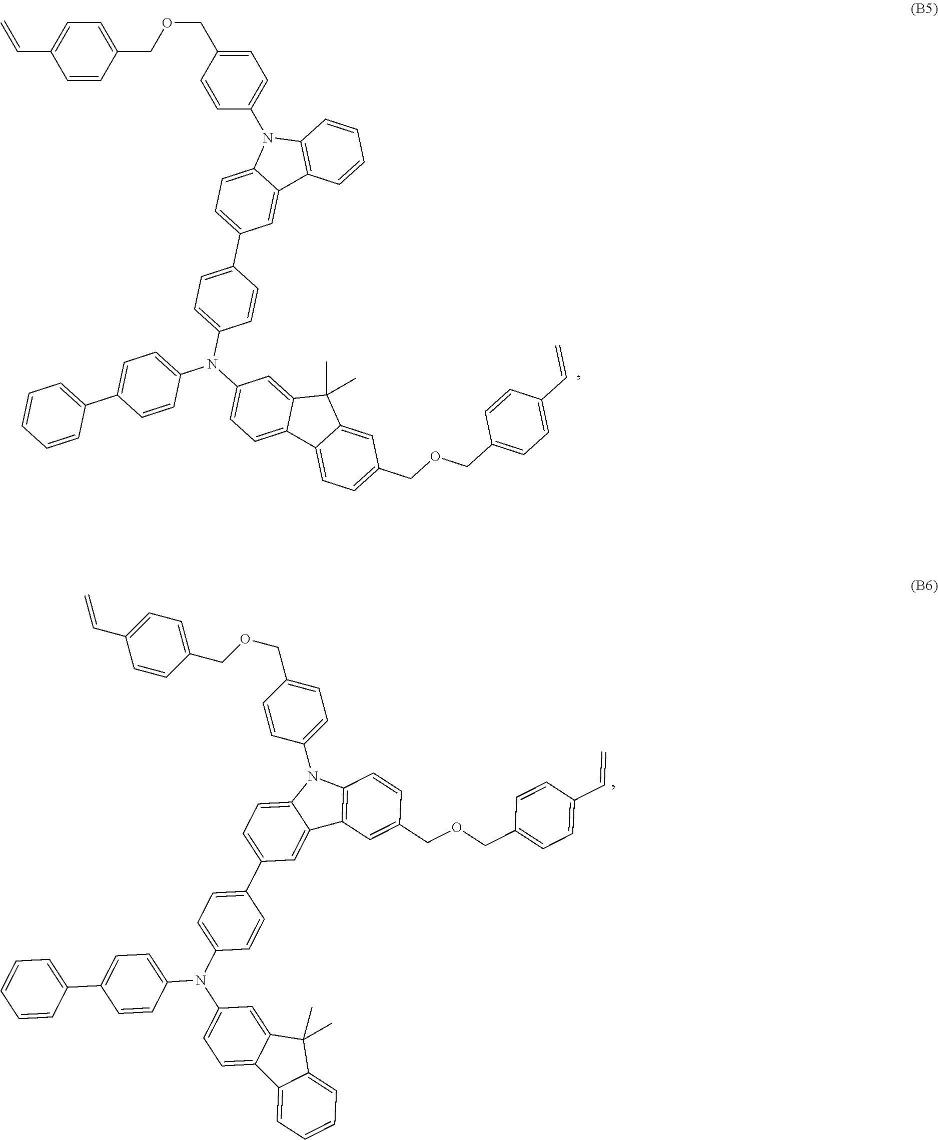 [SMILES: C=Cc1ccc(COCc2ccc(-n3c4ccccc4c4cc(-c5ccc(N(c6ccc(-c7ccccc7)cc6)c6ccc7c(c6)C(C)(C)c6cc(COCc8ccc(C=C)cc8)ccc6-7)cc5)ccc43)cc2)cc1 ; C=Cc1ccc(COCc2ccc(-n3c4ccc(COCc5ccc(C=C)cc5)cc4c4cc(-c5ccc(N(c6ccc(-c7ccccc7)cc6)c6ccc7c(c6)C(C)(C)c6ccccc6-7)cc5)ccc43)cc2)cc1]

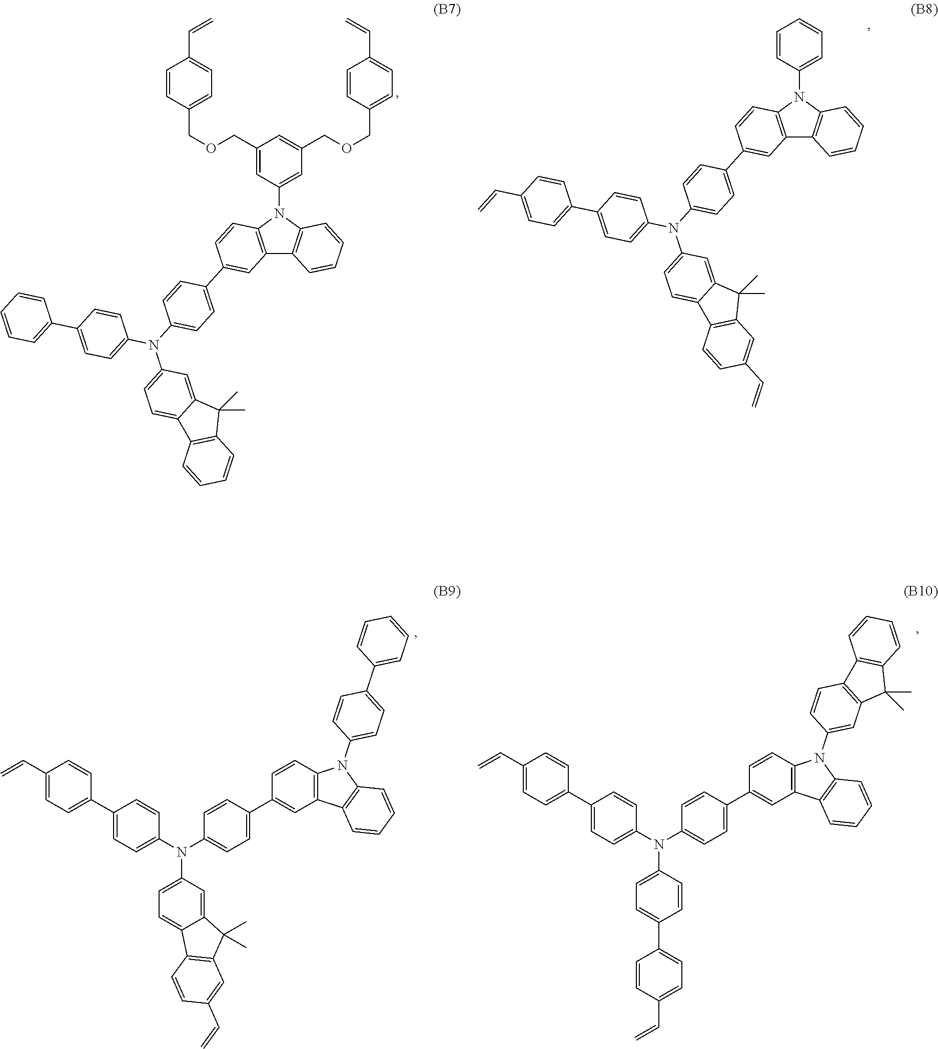 [SMILES: C=Cc1ccc(COCc2cc(COCc3ccc(C=C)cc3)cc(-n3c4ccccc4c4cc(-c5ccc(N(c6ccc(-c7ccccc7)cc6)c6ccc7c(c6)C(C)(C)c6ccccc6-7)cc5)ccc43)c2)cc1 ; C=Cc1ccc(-c2ccc(N(c3ccc(-c4ccc5c(c4)c4ccccc4n5-c4ccccc4)cc3)c3ccc4c(c3)C(C)(C)c3cc(C=C)ccc3-4)cc2)cc1 ; C=Cc1ccc(-c2ccc(N(c3ccc(-c4ccc5c(c4)c4ccccc4n5-c4ccc(-c5ccccc5)cc4)cc3)c3ccc4c(c3)C(C)(C)c3cc(C=C)ccc3-4)cc2)cc1 ; C=Cc1ccc(-c2ccc(N(c3ccc(-c4ccc(C=C)cc4)cc3)c3ccc(-c4ccc5c(c4)c4ccccc4n5-c4ccc5c(c4)C(C)(C)c4ccccc4-5)cc3)cc2)cc1]

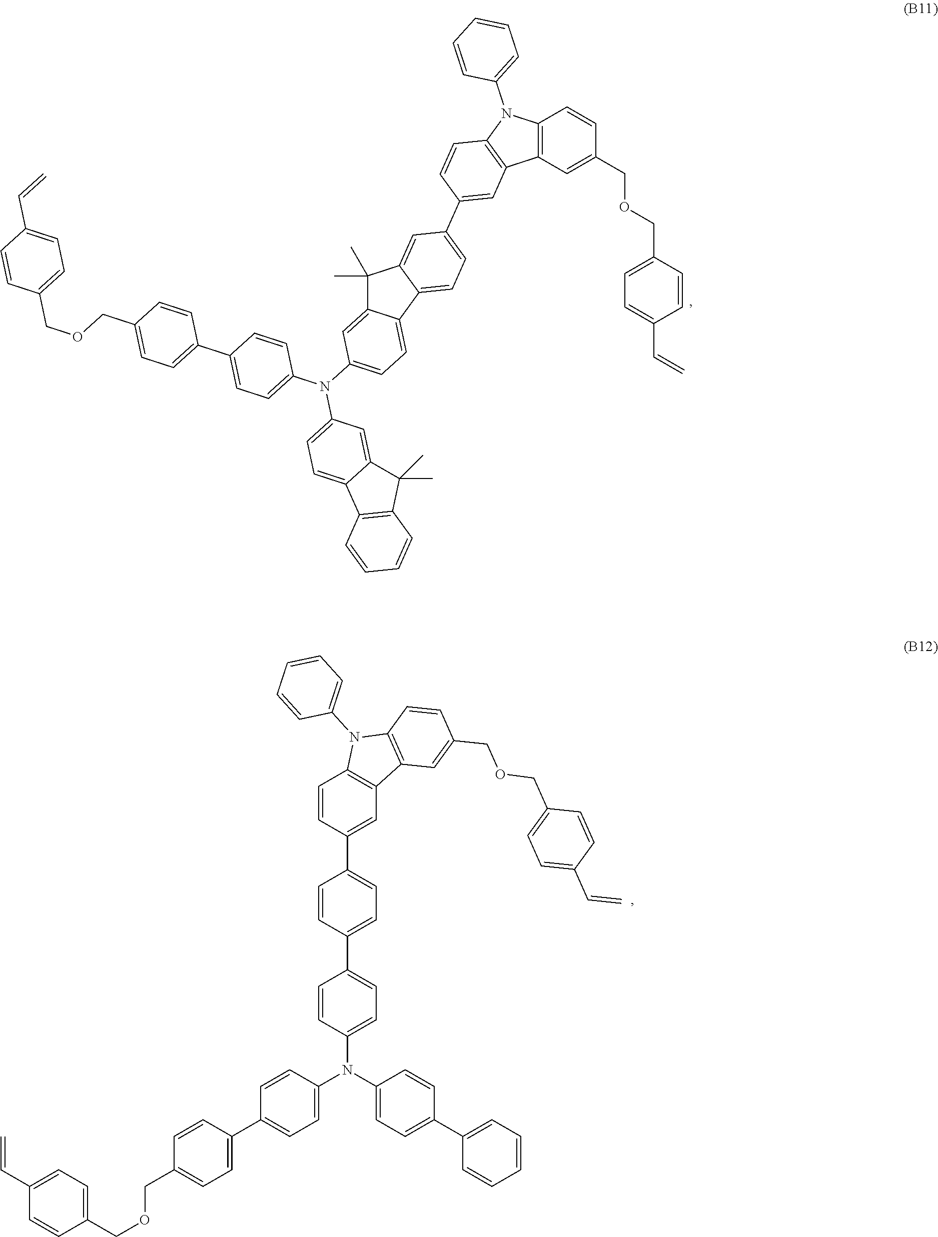

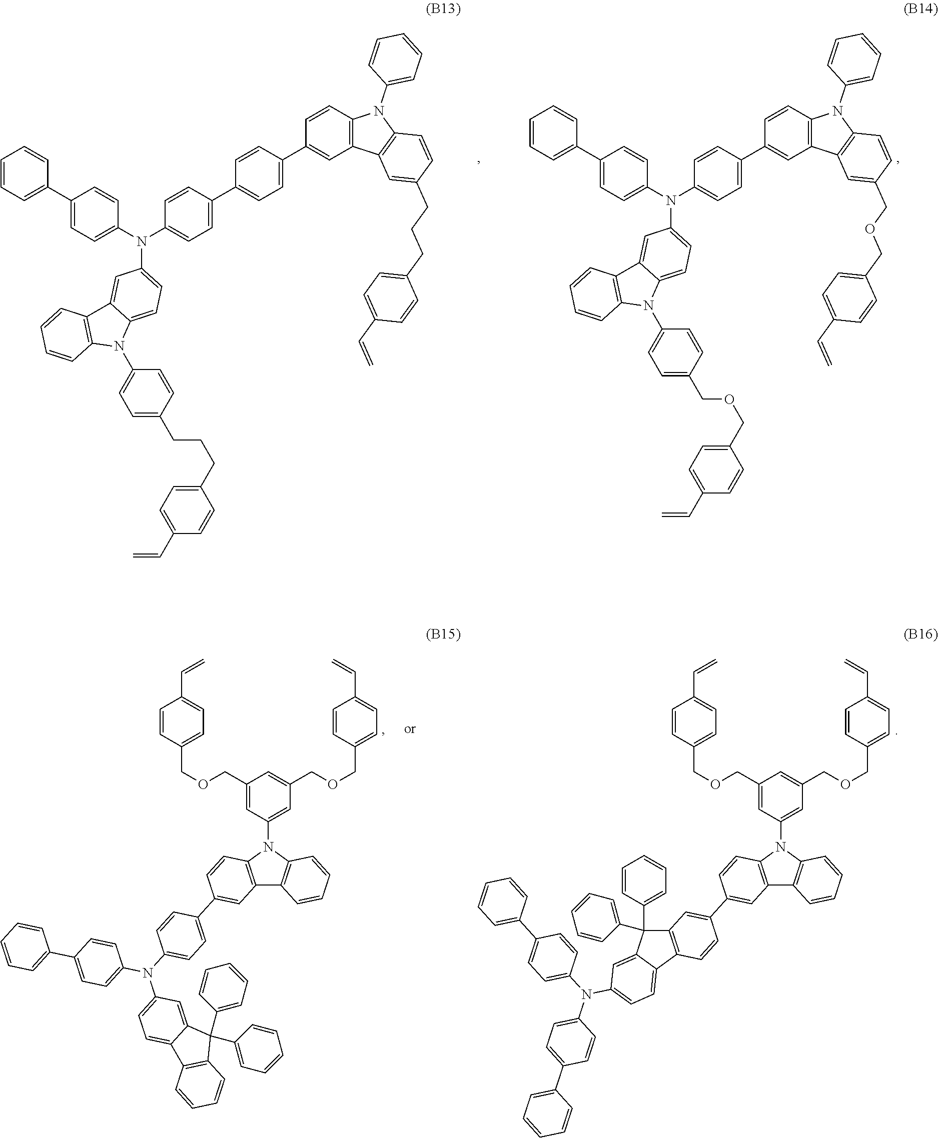

Monomer B useful in the present invention may have a molecular weight of from 500 g/mole to 28,000 g/mole, from 700 g/mole to 14,000 g/mole, from 1,000 g/mole to 4,000 g/mole, or from 1,500 g/mole to 3,000 g/mole.

In one embodiment, Monomer B is further purified through ion exchange beads to remove cationic impurities and anionic impurities, such as metal ion, sulfate ion, formate ion, oxalate ion and acetate ion. The purity of Monomer B may be equal to or above 99%, equal to or above 99.4%, or even equal to or above 99.5%. The said purify is achieved through well-known methods in the art to remove the impurities, for example, fractionation, sublimation, chromatography, crystallization and precipitation methods.

Monomer B useful in the present invention may be present in an amount of at least 54% by mole, 70% by mole or more, 80% by mole or more, 90% by mole or more, or even 100% by mole, based on the total moles of monomers in the composition. Preferably, the composition comprises 100% by mole of Monomer B based on the total moles of monomers in the composition.

The composition useful in the present invention may further comprise one or more additional monomers that are different from Monomer B. The additional monomers may include compounds that contain at least one group, preferably two groups, having the structure of Structure D described above. The additional monomers may be present, based on the total moles of monomers in the composition, from 0 to 46% by mole, or 30% by mole or less, 20% by mole or less, 10% by mole or less, or even 5% by mole or less. Total monomers in the composition may be present in an amount of 80% by weight or more, 85% by weight or more, or even 88% by weight or more, or 90% by weight or less, and at the same time, 99% by weight or less, 97% by weight or less, 95% by weight or less, or even 93% by weight or less, based on the total weight of the composition.

The composition useful in the present invention further comprises one or more p-dopants. The p-dopants may be selected from ionic compounds including, for example, trityl salts, ammonium salts, iodonium salts, tropylium salts, imidazolium salts, phosphonium salts, oxonium salts, or mixtures thereof. Preferably, the ionic compounds are selected from trityl borates, ammonium borates, iodonium borates, tropylium borates, imidazolium borates, phosphonium borates, oxonium borates, or mixtures thereof. The p-dopants useful in the present invention may be selected from one or more of the following compounds (p-1) through (p-13):

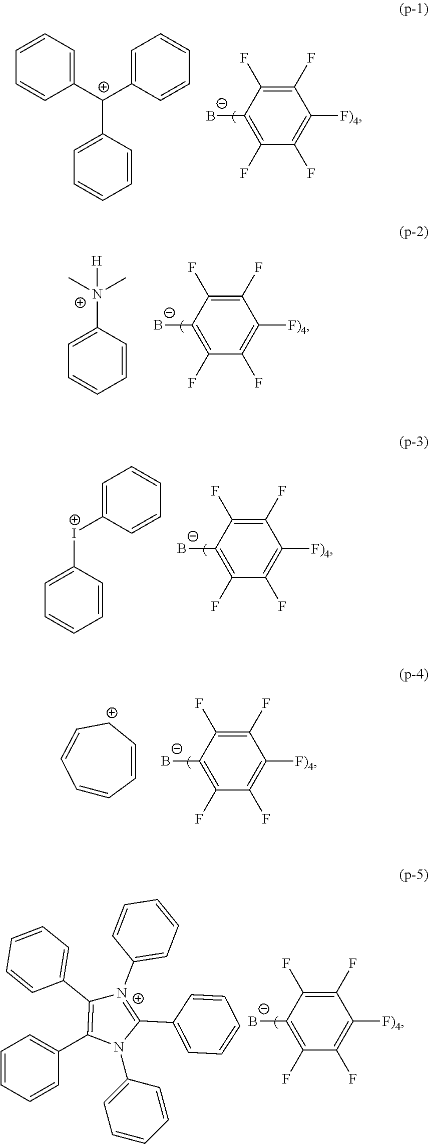

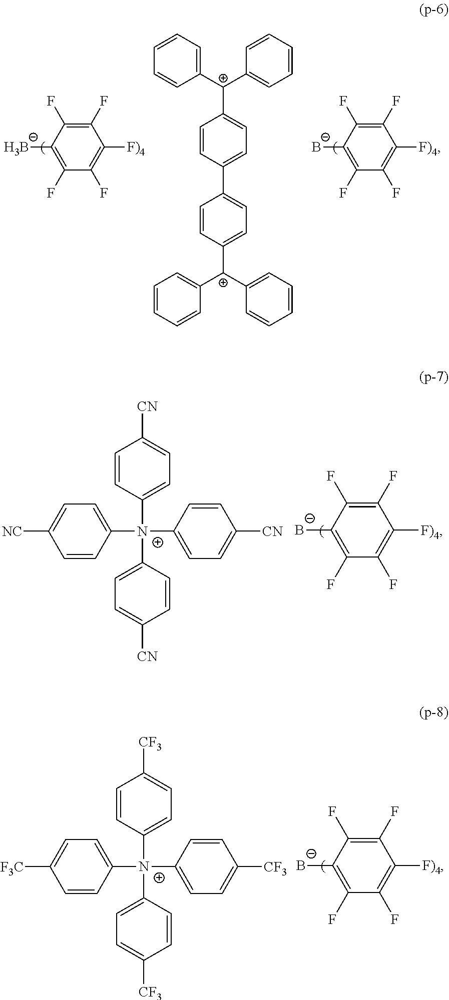

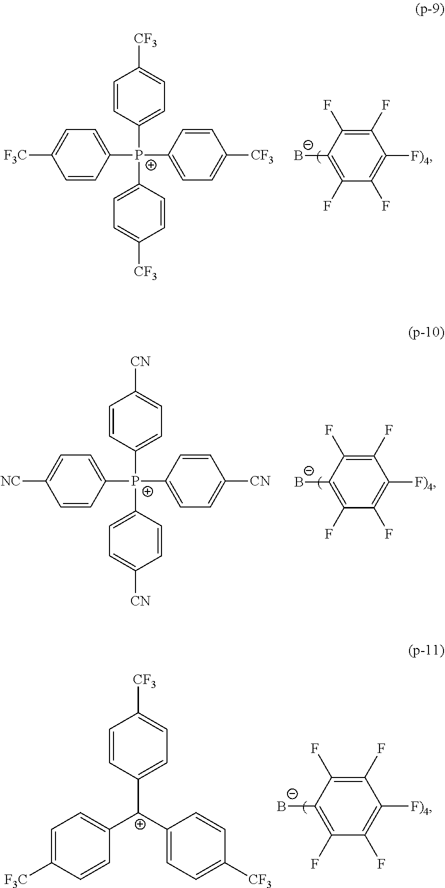

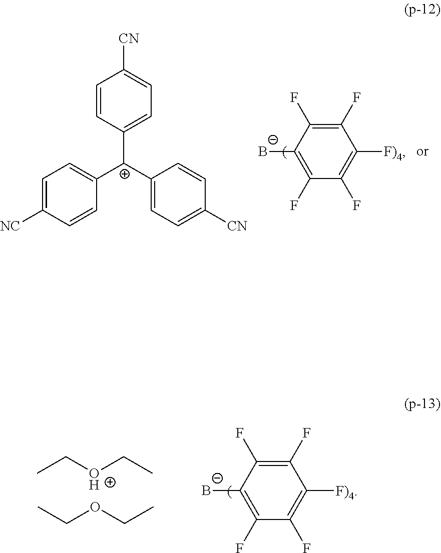

Preferably, the p-dopant useful in the present invention has the following structure:

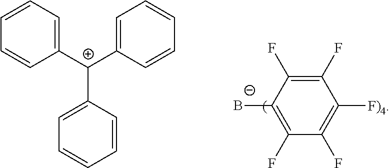

The p-dopant useful in the present invention may be present, based on the total weight of the composition, in an amount of 1% by weight or more, 3% by weight or more, 5% by weight or more, or even 7% by weight or more, and at the same time, 20% by weight or less, 15% by weight or less, 12% by weight or less, or even 10% by weight or less.

The polymeric layer of the present invention may be formed by crosslinking the composition described above. Without being bound by a theory, the p-dopant in the composition would achieve cationic polymerization with terminal vinyl groups of Monomer B and other monomers if present. The polymeric layer of the present invention provides an electronic device comprising thereof with significantly lower driving voltage than a polymeric layer formed from a composition that does not contain the p-dopant, and significantly higher efficiency than a layer comprising NPB.

The present invention also relates to a polymeric layer comprising segments derived from the p-dopants after crosslinking; and a polymer comprising, as polymerized units, from 54% to 100% by mole, from 70% to 100% by mole, from 80% to 100% by mole, or from 90% to 100% by mole, of Monomer B, based on the total moles of the polymer. The polymer in the polymeric layer forms a crosslinked structure.

The present invention also provides a method of making a polymeric layer suitable for an organic electronic device. The method may comprise: (i) providing the composition, (ii) dissolving or dispersing the composition in one or more organic solvents to obtain a crosslinkable solution, (iii) depositing the crosslinkable solution to a substrate, and (iv) crosslinking and drying the crosslinkable solution to form the polymeric layer. The organic solvents may include those used in the fabrication of an organic electronic device by solution process. Suitable organic solvents may include tetrahydrofuran (THF), cyclohexanone, chloroform, 1,4-dioxane, acetonitrile, ethyl acetate, tetralin, chlorobenzene, toluene, xylene, anisole, mesitylene, tetralone, and combinations thereof. The crosslinkable solution may be first filtered through a membrane or a filter to remove particles larger than 50 nm prior to applying to the substrate.

The crosslinkable solution useful in the method of the present invention may be deposited over a substrate, such as a first electrode, for example, an anode or cathode. The deposition may be performed by any of various types of solution processing techniques known or proposed to be used for fabricating light emitting devices. For example, the crosslinkable solution can be deposited using a printing process, such as inkjet printing, nozzle printing, offset printing, transfer printing, or screen printing; or for example, using a coating process, such as spray coating, spin coating, or dip coating. The crosslinkable solution is further crosslinked and dried to form the polymeric layer. Crosslinking and drying may be performed by exposing the crosslinkable solution to heat and/or actinic radiation, including ultraviolet (UV) light, gamma rays, or x-rays. Crosslinking may be carried out in the presence of an initiator that decomposed under heat or irradiation to produce free radicals or ions that initiate the crosslinking reaction. Temperatures for crosslinking and drying may be in the range of 150° C. to 280° C., in the range of 160° C. to 250° C., or in the range of 180° C. to 210° C. The time duration for crosslinking and drying may vary depending on temperature used, for example, from 1 minute (min) to 60 min, from 5 min to 40 min, or from 10 min to 30 min. Crosslinking and drying may be performed in-situ during the fabrication of a device. After crosslinking and drying, the polymeric layer made thereof is preferably free of residual moieties which are reactive or decomposable with exposure to light, positive charges, negative charges or excitons. The steps of solution deposition, crosslinking and drying can be repeated to make multiple layers. The polymeric layer can be an emissive layer or a charge transfer layer such as a hole transport layer, an electron transport layer, or a hole injection layer in organic electronic devices.

The present invention also provides an organic electronic device comprising the polymeric layer of the present invention. The organic electronic device can be an organic light emitting device. The organic light emitting device useful in the present invention may comprise a first conductive layer, an electron transport layer (ETL) and a hole transport layer (HTL) and a second conductive layer. In one embodiment, the hole transport layer, as the typical polymeric layer, is prepared according to the above process. The first conductive layer is used as an anode and in general is a transparent conducting oxide, for example, fluorine-doped tin oxide, antimony-doped tin oxide, zinc oxide, aluminum-doped zinc oxide, indium tin oxide, metal nitride, metal selenide and metal sulfide. The second conductive layer is a cathode and comprises a conductive material. It is preferred that the material has a good thin film-forming property to ensure sufficient contact between the second conductive layer and hole transport layer to promote the electron injection under low voltage and provide better stability. For example, the material of the cathode can be a metal such as aluminum and calcium, a metal alloy such as magnesium/silver and aluminum/lithium, and any combination thereof. Moreover, an extremely thin film of lithium fluoride may be optionally placed between the cathode and the emitting layer. Lithium fluoride can effectively reduce the energy barrier of injecting electrons from the cathode to the emitting layer. In addition, the emitting layer plays a very important role in the whole structure of the light emitting device. In addition to determining the color of the device, the emitting layer also has an important impact on the luminance efficiency in a whole. Common luminescent materials can be classified as fluorescence and phosphorescence depending on the light emitting mechanism.

The term “organic electronic device” refers to a device that carries out an electrical operation with the presence of organic materials. Specific examples of organic electronic devices include organic photovoltaics; organic sensors; organic thin film transistors, organic memory devices, organic field effect transistors; and organic light emitting devices such as OLED devices; and power generation and storage devices such as organic batteries, fuel cells, and organic super capacitors.

The term “organic light emitting device” refers to a device that emits light when an electrical current is applied across two electrodes. Specific example includes light emitting diodes.

The term “p-dopant” refers to an additive that can increase the hole conductivity of a charge transfer layer.

The term “charge transfer layer” refers to a material that can transport charge carrying moieties, either holes or electrons. Specific example includes hole transport layer.

The term “aromatic moiety” refers to an organic moiety derived from aromatic hydrocarbyl by deleting at least one hydrogen atom therefrom. An aromatic moiety may be a monocyclic and/or fused ring system, each ring of which suitably contains from 4 to 7, preferably from 5 or 6 atoms. Structures wherein two or more aromatic moieties are combined through single bond(s) are also included. Specific examples include phenyl, naphthyl, biphenyl, anthryl, indenyl, fluorenyl, benzofluorenyl, phenanthryl, triphenylenyl, pyrenyl, perylenyl, chrysenyl, naphtacenyl, and fluoranthenyl. The naphthyl may be 1-naphthyl or 2-naphthyl, the anthryl may be 1-anthryl, 2-anthryl or 9-anthryl, and the fluorenyl may be any one of 1-fluorenyl, 2-fluorenyl, 3-fluorenyl, 4-fluorenyl and 9-fluorenyl.

The term “heteroaromatic moiety” refers to an aromatic moiety, in which at least one carbon atom or CH group or CH₂ group is substituted with a heteroatom or a chemical group containing at least one heteroatom. The heteroaromatic moiety may be a 5- or 6-membered monocyclic heteroaryl, or a polycyclic heteroaryl which is fused with one or more benzene ring(s), and may be partially saturated. The structures having one or more heteroaromatic moieties bonded through a single bond are also included. Specific examples include monocyclic heteroaryl groups, such as furyl, thiophenyl, pyrrolyl, imidazolyl, pyrazolyl, thiazolyl, thiadiazolyl, isothiazolyl, isoxazolyl, oxazolyl, oxadiazolyl, triazinyl, tetrazinyl, triazolyl, tetrazolyl, furazanyl, pyridyl, pyrazinyl, pyrimidinyl, pyridazinyl; polycyclic heteroaryl groups, such as benzofuranyl, fluoreno[4, 3-b]benzofuranyl, benzothiophenyl, fluoreno[4, 3-b]benzothiophenyl, isobenzofuranyl, benzimidazolyl, benzothiazolyl, benzisothiazolyl, benzisoxazolyl, benzoxazolyl, isoindolyl, indolyl, indazolyl, benzothia-diazolyl, quinolyl, isoquinolyl, cinnolinyl, quinazolinyl, quinoxalinyl, carbazolyl, phenanthridinyl and benzodioxolyl.

The term “hydrocarbyl” refers to a chemical group containing only hydrogen and carbon atoms.

The term “substituted hydrocarbyl” refers to a hydrocarbyl in which at least one hydrogen atom is substituted with a heteroatom or a chemical group containing at least one heteroatom.

The term “heterohydrocarbyl” refers to a chemical group containing hydrogen and carbon atoms, and wherein at least one carbon atom or CH group or CH₂ group is substituted with a heteroatom or a chemical group containing at least one heteroatom.

The term “substituted heterohydrocarbyl” refers to a heterohydrocarbyl in which at least one hydrogen atom is substituted with a heteroatom or a chemical group containing at least one heteroatom.

The term “aryl” refers to an organic radical derived from aromatic hydrocarbyl by deleting one hydrogen atom therefrom. An aryl group may be a monocyclic and/or fused ring system, each ring of which suitably contains from 4 to 7, preferably from 5 or 6 atoms. Structures wherein two or more aryl groups are combined through single bond(s) are also included. Specific examples include phenyl, naphthyl, biphenyl, anthryl, indenyl, fluorenyl, benzofluorenyl, phenanthryl, triphenylenyl, pyrenyl, perylenyl, chrysenyl, naphtacenyl, and fluoranthenyl. The naphthyl may be 1-naphthyl or 2-naphthyl, the anthryl may be 1-anthryl, 2-anthryl or 9-anthryl, and the fluorenyl may be any one of 1-fluorenyl, 2-fluorenyl, 3-fluorenyl, 4-fluorenyl and 9-fluorenyl. The term “arylene”, refers to an organic radical derived from aryl by deleting one hydrogen atom therefrom.

The term “substituted aryl” refers to an aryl in which at least one hydrogen atom is substituted with a heteroatom or a chemical group containing at least one heteroatom.

The term “heteroaryl” refers to an aryl group, in which at least one carbon atom or CH group or CH₂ group is substituted with a heteroatom or a chemical group containing at least one heteroatom. The heteroaryl may be a 5- or 6-membered monocyclic heteroaryl or a polycyclic heteroaryl which is fused with one or more benzene ring(s), and may be partially saturated. The structures having one or more heteroaryl group(s) bonded through a single bond are also included. The heteroaryl groups may include divalent aryl groups of which the heteroatoms are oxidized or quarternized to form N-oxides, quaternary salts, or the like. Specific examples include, but are not limited to, monocyclic heteroaryl groups, such as furyl, thiophenyl, pyrrolyl, imidazolyl, pyrazolyl, thiazolyl, thiadiazolyl, isothiazolyl, isoxazolyl, oxazolyl, oxadiazolyl, triazinyl, tetrazinyl, triazolyl, tetrazolyl, furazanyl, pyridyl, pyrazinyl, pyrimidinyl, pyridazinyl; polycyclic heteroaryl groups, such as benzofuranyl, fluoreno[4, 3-b]benzofuranyl, benzothiophenyl, fluoreno[4, 3-b]benzothiophenyl, isobenzofuranyl, benzimidazolyl, benzothiazolyl, benzisothiazolyl, benzisoxazolyl, benzoxazolyl, isoindolyl, indolyl, indazolyl, benzothia-diazolyl, quinolyl, isoquinolyl, cinnolinyl, quinazolinyl, quinoxalinyl, carbazolyl, phenanthridinyl and benzodioxolyl; and corresponding N-oxides (for example, pyridyl N-oxide, quinolyl N-oxide) and quaternary salts thereof. The term “heteroarylene”, refers to an organic radical derived from heteroaryl by deleting one hydrogen atom therefrom.

The term “substituted heteroaryl” refers to a heteroaryl in which at least one hydrogen atom is substituted with a heteroatom or a chemical group containing at least one heteroatom.

Heteroatoms include O, N, P, P(═O), Si, B and S.

The term “monomer” refers to a compound containing one or more functional groups (for example, Structure D) that is able to be polymerized into a polymer.

The term “polymer” refers to a polymeric compound prepared by polymerizing monomers, whether of the same or a different type. The generic term polymer thus embraces the term homopolymer (employed to refer to polymers prepared from only one type of monomer, with the understanding that trace amounts of impurities can be incorporated into and/or within the polymer structure), and the term interpolymer as defined hereinafter.

The term “interpolymer” refers to polymers prepared by the polymerization of at least two different types of monomers. The generic term interpolymer thus includes copolymers (employed to refer to polymers prepared from two different types of monomers), and polymers prepared from more than two different types of monomers.

### EXAMPLES

The following examples illustrate embodiments of the present invention. All parts and percentages are by weight unless otherwise indicated.

All solvents and reagents are available from commercial vendors, for example, Sigma-Aldrich, TCI, and Alfa Aesar, and are used in the highest available purities, and/or when necessary, recrystallized before use. Dry solvents were obtained from in-house purification/dispensing system (hexane, toluene, and tetrahydrofuran), or purchased from Sigma-Aldrich. All experiments involving “water sensitive compounds” are conducted in “oven dried” glassware, under nitrogen atmosphere, or in a glovebox.

The following standard analytical equipment and methods are used in the Examples.

### Nuclear Magnetic Resonance (NMR)

¹H-NMR spectra (500 MHZ or 400 MHZ) were obtained on a Varian VNMRS-500 or VNMRS-400 spectrometer at 30° C. The chemical shifts are referenced to tetramethyl silane (TMS) (6:000) in CDCl₃.

### Liquid Chromatography-Mass Spectrometry (LC/MS)

Routine liquid chromatography/mass spectrometry (LC/MS) studies were carried out as follows. One microliter aliquots of the sample, as “1 mg/ml solution in tetrahydrofuran (THF),” are injected on an Agilent 1200SL binary liquid chromatography (LC), coupled to an Agilent 6520 quadruple time-of-flight (Q-TOF) MS system, via a dual electrospray interface (ESI), operating in the PI mode. The following analysis conditions are used: Column: Agilent Eclipse XDB-C18, 4.6*50 mm, 1.7 um; Column oven temperature: 30° C.; Solvent A: THF; Solvent B: 0.1% formic acid in water/Acetonitrile (v/v, 95/5); Gradient: 40-80% Solvent A in 0-6 min, and held for 9 min; Flow: 0.3 mL/min; UV detector: diode array, 254 nm; MS condition: Capillary Voltage: 3900 kV (Neg), 3500 kV (Pos); Mode: Neg and Pos; Scan: 100-2000 amu; Rate: Is/scan; Desolvation temperature: 300° C.

### Synthesis of Monomer B1

### Synthesis of N-phenyl-[1,1′-biphenyl]-4-amine (Compound 1)

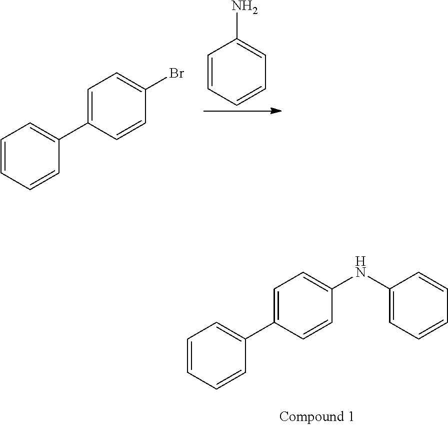

A mixture of aniline (6.52 g, 70 mmol), 4-bromobiphenyl (11.6 g, 50 mmol), Pd(OAc)₂ (224 mg, 1 mmol), 2,2′-bis(diphenylphosphino)-1,1′-binaphthyl (BINAP) (622 mg, 1 mmol), Potassium tert-butoxide (tBuOK) (7.84 g, 70 mmol) in 60 mL dry toluene was refluxed under nitrogen atmosphere for 12 h. After cooling to room temperature, the solvent was removed under vacuum and the residue was extracted with dichloromethane. The organic layer was separated and washed consecutively with saturated sodium bicarbonate solution, brine, and dried over anhydrous sodium sulphate. After filtration, the solvent was removed under vacuum and the residue was purified through column chromatography to give white solid (yield: 82%). MS (ESI): 246.13 [M+H]⁺. ¹H-NMR (CDCl₃, 400 MHz, TMS, ppm): δ 7.50 (d, 2H), 7.45 (d, 2H), 7.34 (t, 2H), 7.24-7.20 (m, 3H), 7.08-7.04 (m, 4H), 6.88 (m, 1H).

### Synthesis of N-([1,1′-biphenyl]-4-yl)-7-bromo-9,9-dimethyl-N-phenyl-9H-fluoren-2-amine (Compound 2)

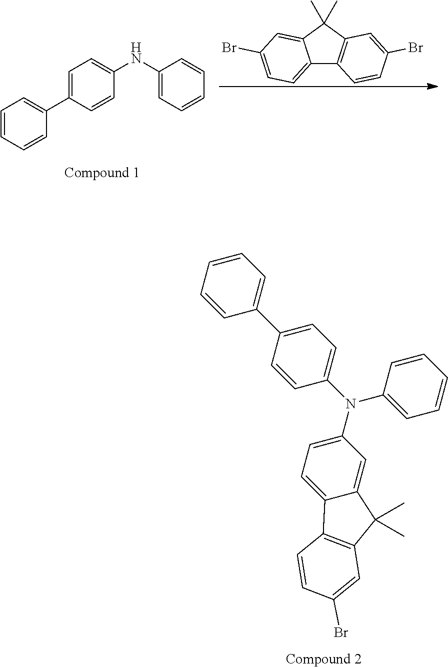

A mixture of Compound 1 obtained above (2.45 g, 10 mmol), 2,7-dibromo-9,9-dimethyl-9H-fluorene (10.5 g, 30 mmol), Pd(OAc)₂ (44.8 mg, 0.2 mmol), BINAP (124 mg, 0.2 mmol), tBuOK (2.24 g, 20 mmol) in 30 mL dry toluene was heated to 90° C. under nitrogen atmosphere for 12 h. After cooling to room temperature, the solvent was removed under vacuum and the residue was extracted with dichloromethane. The organic layer was separated and washed consecutively with saturated sodium bicarbonate solution, brine, and dried over anhydrous sodium sulphate. After filtration, the solvent was removed under vacuum and the residue was purified through column chromatography to give white solid (yield: 85%). MS (ESI): 516.38 [M+H]⁺. ¹H-NMR (CDCl₃, 400 MHz, TMS, ppm): δ 7.85 (s, 1H), 7.80 (d, 1H), 7.71 (d, 1H), 7.65 (d, 1H), 7.59 (d, 2H), 7.51 (d, 2H), 7.42 (m, 5H), 7.33 (d, 1H), 7.19 (m, 3H), 7.05 (m, 3H), 1.45 (s, 6H).

### Synthesis of 7-([1,1′-biphenyl]-4-yl(phenyl)amino)-9,9-dimethyl-9H-fluorene-2-carbaldehyde (Compound 3)

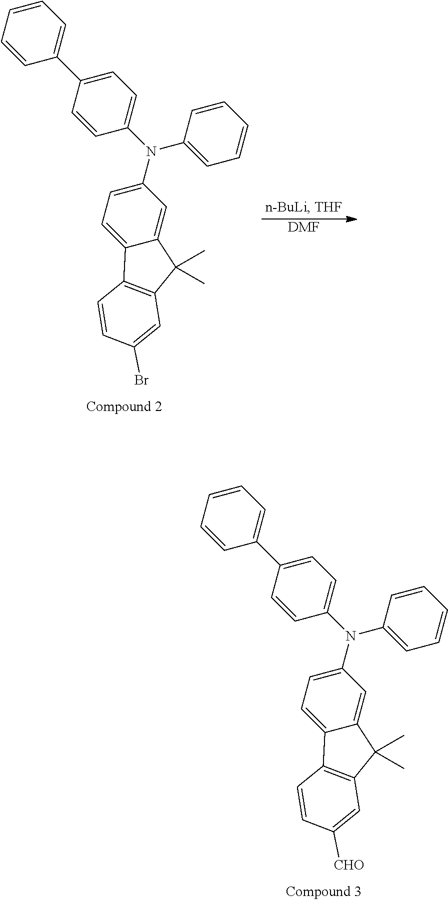

To a solution of Compound 2 obtained above (10 g, 20 mmol) in 300 mL THF at −78° C., 2.4 M nBuLi (10 mL, 24 mmol) was added dropwise in 30 min. After addition, the mixture was stirred at −78° C. for 0.5 h. Then, 2 mL DMF was added to the mixture at −78° C. After addition, the solution was allowed to warm slowly to room temperature and kept stirring overnight. The reaction was quenched with water and the solvent was evaporated. The residue was extracted with CH₂Cl₂ (2×100 mL) and the combined organic layer was dried over anhydrous MgSO₄. After removing solvent, the crude product was purified through column chromatography to give crude product (yield: 65%). MS (ESI): 466.21 [M+H]⁺. ¹H-NMR (CDCl₃, 400 MHz, TMS, ppm): δ 10.10 (s, 1H), 7.93 (s, 1H), 7.86 (d, 1H), 7.71 (d, 1H), 7.65 (d, 1H), 7.59 (d, 2H), 7.51 (d, 2H), 7.42 (m, 5H), 7.33 (d, 1H), 7.19 (m, 3H), 7.05 (m, 3H), 1.45 (s, 6H).

### Synthesis of 7-([1,1′-biphenyl]-4-yl(4-bromophenyl)amino)-9,9-dimethyl-9H-fluorene-2-carbaldehyde (Compound 4)

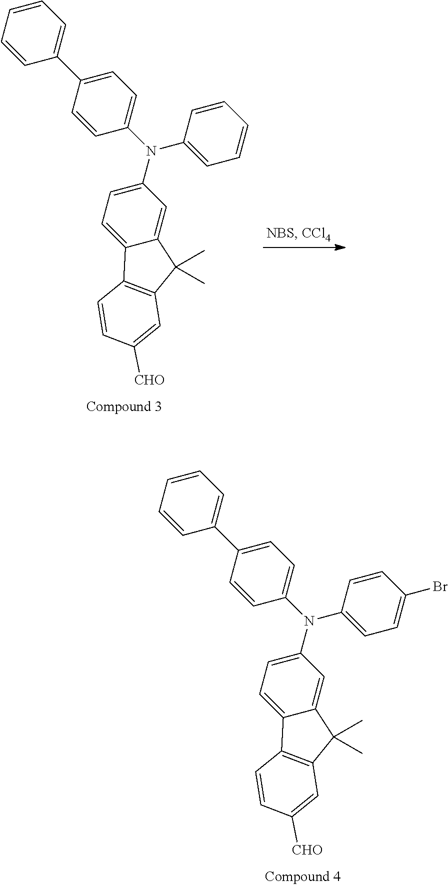 [SMILES: CC1(C)c2cc(C=O)ccc2-c2ccc(N(c3ccccc3)c3ccc(-c4ccccc4)cc3)cc21 ; CC1(C)c2cc(C=O)ccc2-c2ccc(N(c3ccc(Br)cc3)c3ccc(-c4ccccc4)cc3)cc21]

To a solution of Compound 3 obtained above (4.6 g, 10 mmol) in 30 mL DMF, N-bromosuccinimide (NBS) (1.78 g, 10 mmol) was added in portion. After addition, the mixture was stirred overnight and poured into water to precipitate. The solid was filtrated and recrystallized from dichloromethane and petroleum ether to give yellow solid (yield: 87%). MS (ESI): 544.12 [M+H]⁺. ¹H-NMR (CDCl₃, 400 MHz, TMS, ppm): δ 10.02 (s, 1H), 7.91 (s, 1H), 7.83 (d, 1H), 7.76 (d, 1H), 7.66 (d, 1H), 7.60 (d, 2H), 7.53 (d, 2H), 7.43 (m, 4H), 7.33 (d, 1H), 7.19 (m, 3H), 7.07 (m, 3H), 1.45 (s, 6H).

### Synthesis of 7-([1,1′-biphenyl]-4-yl(4-(4,4,5,5-tetramethyl-1,3,2-dioxaborolan-2-yl)phenyl)amino)-9,9-dimethyl-9H-fluorene-2-carbaldehyde (Compound 5)

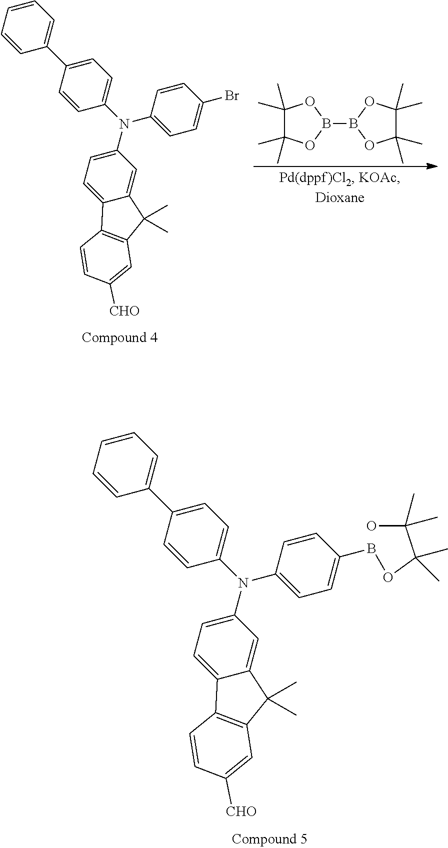

A mixture of Compound 4 obtained above (16.32 g, 30 mmol), 4,4,4′,4′,5,5,5′,5′-octamethyl-2,2′-bi(1,3,2-dioxaborolane) (9.14 g, 36 mmol), Pd(dppf)₂Cl₂ (571 mg, 0.75 mmol), CH₃COOK (4.41 g, 45 mmol) in 60 mL dry dioxane was heated at 85° C. under nitrogen atmosphere for 12 h. After cooling to room temperature, the solvent was removed under vacuum and then water was added. The mixture was extracted with CH₂Cl₂. The organic layer was collected and dried over anhydrous MgSO₄. After filtration, the filtrate was evaporated to remove solvent and the residue was purified through column chromatography on silica gel to give yellow solid (yield: 80%). MS (ESI): 591.62 [M+H]⁺. ¹H-NMR (CDCl₃, 400 MHz, TMS, ppm): δ 10.10 (s, 1H), 7.88 (s, 1H), 7.83 (d, 1H), 7.76 (d, 1H), 7.66 (d, 1H), 7.58 (d, 2H), 7.51 (d, 2H), 7.42 (m, 4H), 7.35 (d, 1H), 7.16 (m, 3H), 7.06 (m, 3H), 1.45 (s, 6H), 1.37 (s, 12H).

### Synthesis of 4-(9H-carbazol-9-yl)benzaldehyde (Compound 6)

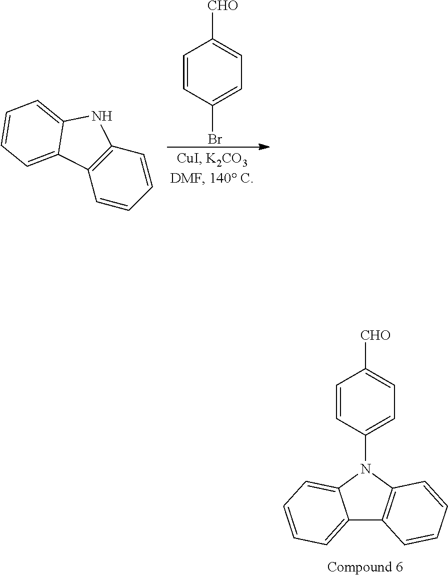 [SMILES: c1ccc2c(c1)[nH]c1ccccc12 ; O=Cc1ccc(Br)cc1 ; O=Cc1ccc(-n2c3ccccc3c3ccccc32)cc1]

A mixture of 9H-carbazole (9.53 g, 57 mmol), 4-bromobenzaldehyde (21.1 g, 114 mmol), copper(I) iodide (1.80 g, 9.4 mmol), K₂CO₃ (11.8 g, 86 mmol) in 60 mL dry DMF was heated to 140° C. under nitrogen atmosphere for 12 h. After cooling to room temperature, the inorganic solid was filtrated and the residue was poured into ice water to precipitate. The so-formed solid was collected and washed by water, ethanol several times, then crystallized from CH₂Cl₂ and ethanol to give light-yellow solid (yield: 95%). MS (ESI): 272.10 [M+H]⁺. ¹H-NMR (CDCl₃, 400 MHz, TMS, ppm): δ 10.14 (s, 1H), 8.29 (d, 2H), 8.22 (d, 2H), 7.93 (d, 2H), 7.54 (d, 2H), 7.49 (t, 2H), 7.36 (t, 2H).

### Synthesis of 4-(3-bromo-9H-carbazol-9-yl)benzaldehyde (Compound 7)

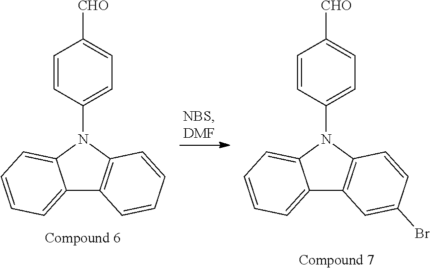 [SMILES: O=Cc1ccc(-n2c3ccccc3c3ccccc32)cc1 ; O=Cc1ccc(-n2c3ccccc3c3cc(Br)ccc32)cc1]

To a solution of Compound 6 obtained above (26.6 g, 98 mmol) in 100 mL DMF, NBS (17.4 g, 98 mmol) in 100 mL DMF was added dropwise in 30 min. After addition, the mixture was stirred at room temperature for 12 h. The solution was poured into ice water to precipitate. After filtration, the solid was collected and washed by water, ethanol several times, then dried under vacuum and used for the next step without further purification (yield: 96%). MS (ESI): 350.01 [M+H]⁺. ¹H-NMR (CDCl₃, 400 MHz, TMS, ppm): δ 10.12 (s, 1H), 8.26 (s, 1H), 8.15 (d, 2H), 8.10 (d, 1H), 7.77 (d, 2H), 7.50 (m, 3H), 7.34 (m, 2H).

### Synthesis of 7-([1,1′-biphenyl]-4-yl(4-(9-(4-formylphenyl)-9H-carbazol-3-yl)phenyl)amino)-9,9-dimethyl-9H-fluorene-2-carbaldehyde (Compound 8)

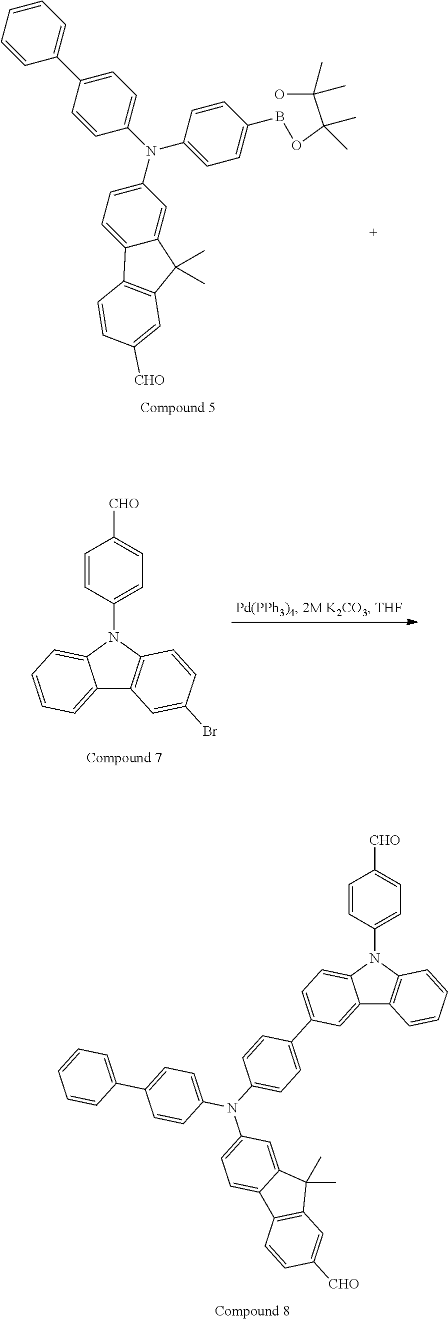

A mixture of Compound 5 obtained above (1.04 g, 1.76 mmol), Compound 7 obtained above (0.51 g, 1.47 mmol), Pd(PPh₃)₄ (76 mg, 0.064 mmol), 2M K₂CO₃ (0.8 g, 6 mmol, 3 mL H₂O), 3 mL ethanol and 3 mL of toluene was heated at 90° C. under nitrogen atmosphere for 12 h. After cooling to room temperature, the solvent was removed under vacuum and the residue was dissolved with CH₂Cl₂. The organic layer was washed with water and then dried over anhydrous sodium sulphate. After filtration, the filtrate was evaporated to remove solvent and the residue was purified through column chromatography on silica gel to give white solid (yield: 85%). MS (ESI): 735.29 [M+H]⁺. ¹H-NMR (CDCl₃, 400 MHz, TMS, ppm): δ 10.13 (s, 1H), 10.03 (s, 1H), 8.36 (s, 1H), 8.20 (d, 1H), 8.14 (d, 2H), 7.92 (s, 1H), 7.65 (m, 3H), 7.77 (d, 1H), 7.67 (m, 4H), 7.63 (d, 2H), 7.54 (m, 4H), 7.44 (m, 3H), 7.35 (m, 7H), 7.16 (d, 1H), 1.48 (s, 6H).

### Synthesis of N-([1,1′-biphenyl]-4-yl)-9,9-dimethyl-6-vinyl-N-(4-(9-(4-vinylphenyl)-9H-carbazol-3-yl)phenyl)-9H-fluoren-2-amine (Monomer B1, 99.5% Purity)

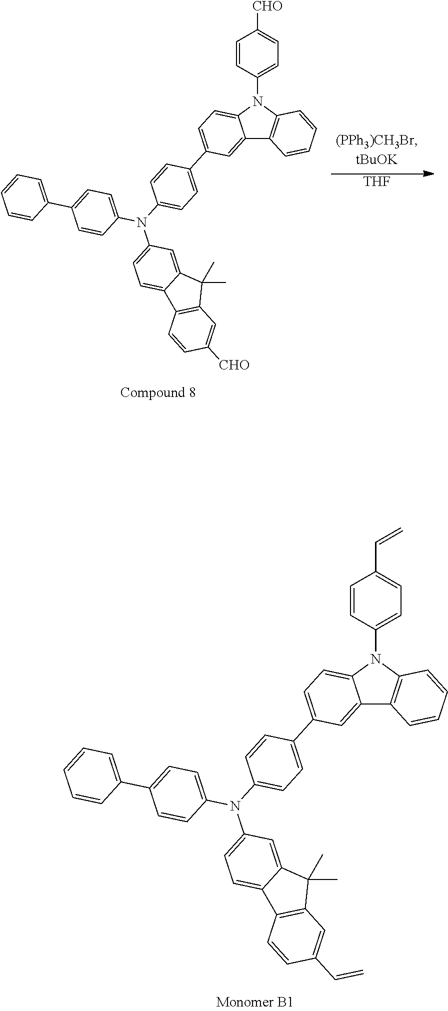 [SMILES: CC1(C)c2cc(C=O)ccc2-c2ccc(N(c3ccc(-c4ccccc4)cc3)c3ccc(-c4ccc5c(c4)c4ccccc4n5-c4ccc(C=O)cc4)cc3)cc21 ; "THF" ; C=Cc1ccc(-n2c3ccccc3c3cc(-c4ccc(N(c5ccc(-c6ccccc6)cc5)c5ccc6c(c5)C(C)(C)c5cc(C=C)ccc5-6)cc4)ccc32)cc1]

To a solution of Ph₃PBrMe (1.428 g, 4 mmol) in 10 mL THF at 0° C., tBuOK (672 mg, 6 mmol) was added under nitrogen atmosphere. After stirring for 30 min, a solution of Compound 8 obtained above (734 mg, 1 mmol) in 10 mL THF was added to the above mixture. Then, the solution was allowed to stir at room temperature for 12 h. After quenching with water, the solvent was removed under vacuum and the residue was dissolved with CH₂Cl₂. The organic layer was washed with water and then dried over anhydrous sodium sulphate. After filtration, the filtrate was evaporated to remove solvent and the residue was purified through column chromatography on silica gel to give white solid (yield: 85%). MS (ESI): 731.34 [M+H]⁺. ¹H-NMR (d⁶-DMSO, 400 MHz, TMS, ppm): δ 8.54 (s, 1H), 8.38 (d, 1H), 7.85 (m, 4H), 7.64 (m, 4H), 7.43 (m, 12H), 7.30 (d, 2H), 7.18 (m, 4H), 7.08 (d, 2H), 6.83 (dd, 2H), 5.89 (d, 2H), 5.36 (d, 2H), 1.45 (s, 6H).

### Synthesis of Monomer B5

### Synthesis of (7-([1,1′-biphenyl]-4-yl(4-(9-(4-(hydroxymethyl)phenyl)-9H-carbazol-3-yl)phenyl)amino)-9,9-dimethyl-9H-fluoren-3-yl)methanol (Compound 9)

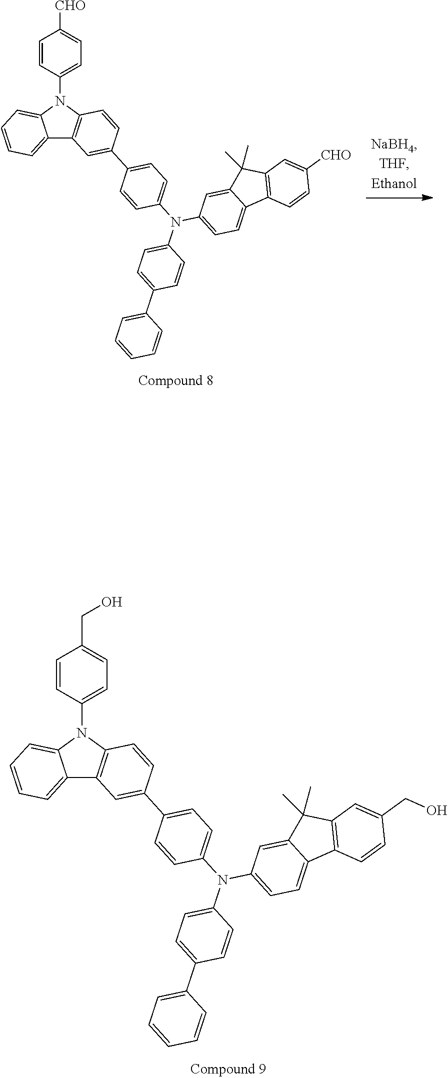 [SMILES: CC1(C)c2cc(C=O)ccc2-c2ccc(N(c3ccc(-c4ccccc4)cc3)c3ccc(-c4ccc5c(c4)c4ccccc4n5-c4ccc(C=O)cc4)cc3)cc21 ; CC1(C)c2cc(CO)ccc2-c2ccc(N(c3ccc(-c4ccccc4)cc3)c3ccc(-c4ccc5c(c4)c4ccccc4n5-c4ccc(CO)cc4)cc3)cc21]

To a solution of Compound 8 obtained above (734 mg, 1 mmol) in 10 mL THF and 10 mL ethanol at 40° C., NaBH₄ (302 mg, 8 mmol) was added under nitrogen atmosphere. The solution was allowed to stir at room temperature for 2 h. Then, aqueous hydrochloric acid solution was added until pH5 and the mixture was kept stirring for 30 min. The solvent was removed under vacuum and the residue was extracted with dichloromethane.

The product was then dried under vacuum and used for the next step without further purification. MS (ESI): 739.32 [M+H]⁺. ¹H-NMR (CDCl₃, 400 MHz, TMS, ppm): δ 8.35 (s, 1H), 8.19 (d, 1H), 7.62 (m, 12H), 7.51 (d, 2H), 7.42 (m, 6H), 7.31 (m, 7H), 7.15 (d, 1H), 4.84 (s, 2H), 4.76 (s, 2H), 3.74 (s, 2H), 1.45 (s, 6H).

### Synthesis of N-([1,1′-biphenyl]-4-yl)-9,9-dimethyl-6-(((4-vinylbenzyl)oxy)methyl)-N-(4-(9-(4-(((4-vinylbenzyl)oxy)methyl)phenyl)-9H-carbazol-3-yl)phenyl)-9H-fluoren-2-amine (Monomer B5, 99.7% Purity)

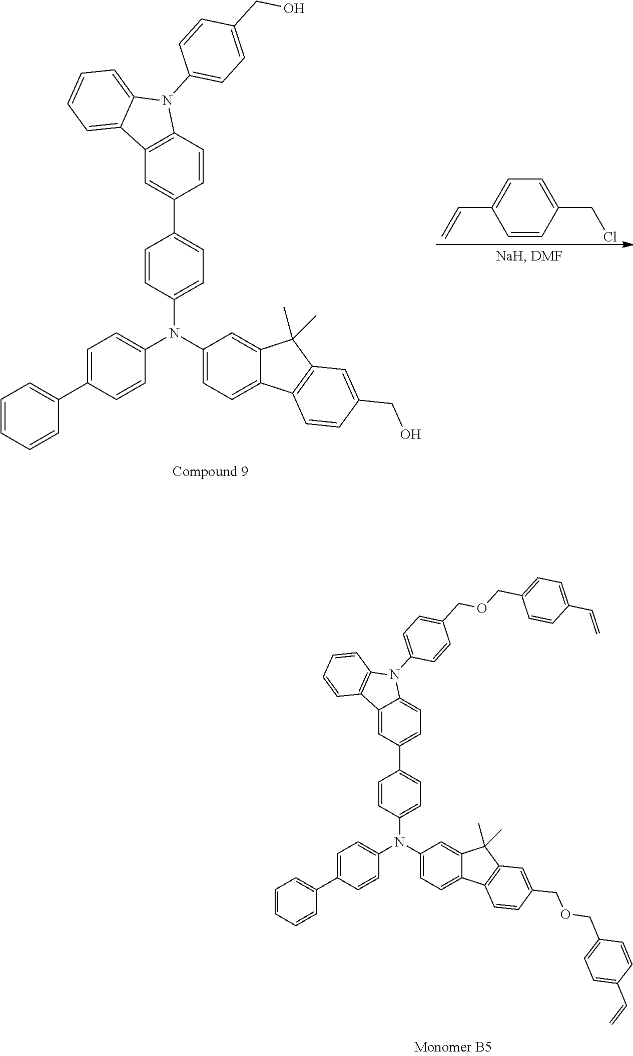

To a solution of Compound 9 obtained above (3.69 g, 5 mmol) in 50 mL dry DMF was added NaH (432 mg, 18 mmol), the mixture was stirred at room temperature for 1 h, and 4-vinylbenzyl chloride (2.11 mL, 2.29 g, 15 mmol) was added to above solution via syringe. The mixture was heated to 60° C. for 24 h. After quenching the reaction with water, the mixture was poured into water to remove DMF. The residue was filtrated and the resulting solid was dissolved in dichloromethane, which was then washed with water. The solvent was removed under vacuum and the residue was extracted with dichloromethane. The product was then obtained by column chromatography on silica gel to give light-yellow solid (yield: 75%). MS (ESI): 971.45 [M+H]⁺. ¹H-NMR (CDCl₃, 400 MHz, TMS, ppm): δ 8.35 (s, 1H), 8.17 (d, 1H), 7.65 (m, 12H), 7.43 (m, 14H), 7.30 (m, 10H), 6.73 (dd, 2H), 5.79 (d, 2H), 5.27 (d, 2H), 4.67 (s, 4H), 4.59 (s, 4H), 1.45 (s, 6H).

### Synthesis of Monomer B4

### Synthesis of N-([1,1′-biphenyl]-4-yl)-9,9-dimethyl-N-(4-(4,4,5,5-tetramethyl-1,3,2-dioxaborolan-2-yl)phenyl)-9H-fluoren-2-amine (Compound 10)

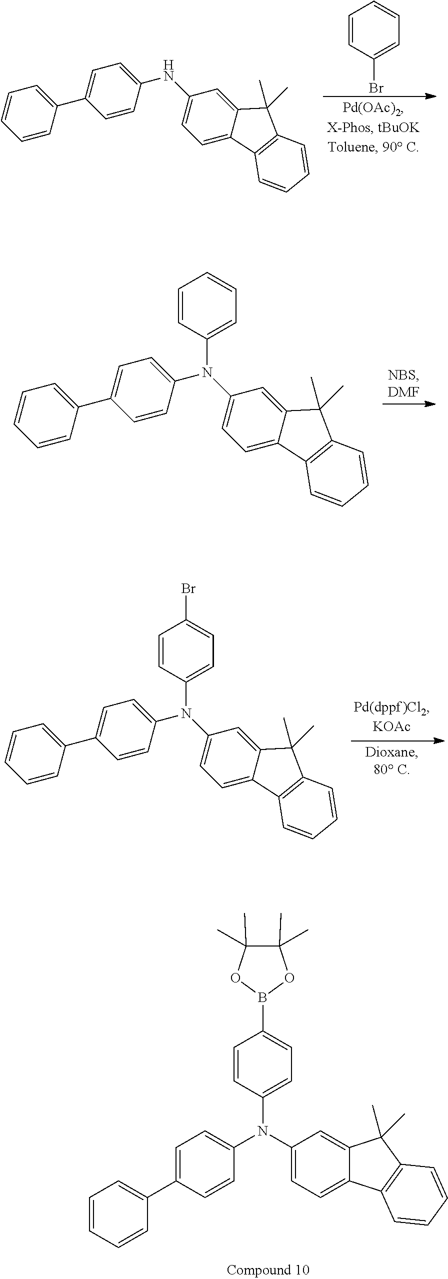 [SMILES: CC1(C)c2ccccc2-c2ccc(Nc3ccc(-c4ccccc4)cc3)cc21 ; Brc1ccccc1 ; CC1(C)c2ccccc2-c2ccc(N(c3ccccc3)c3ccc(-c4ccccc4)cc3)cc21 ; CC1(C)c2ccccc2-c2ccc(N(c3ccc(Br)cc3)c3ccc(-c4ccccc4)cc3)cc21 ; CC1(C)c2ccccc2-c2ccc(N(c3ccc(B4OC(C)(C)C(C)(C)O4)cc3)c3ccc(-c4ccccc4)cc3)cc21]

N-([1,1′-biphenyl]-4-yl)-9,9-dimethyl-9H-fluoren-2-amine (40.0 g, 110 mmol), bromobenzene (23.4 g, 150 mmol), Pd(OAc)₂ (616 mg, 2.75 mmol), X-Phos (1.57 g, 3.3 mmol), tBuOK (24.6 g, 220 mmol) were added into a 250 mL three-necked round-bottom flask equipped with a reflux condenser. After addition of 250 mL dry toluene under N₂ atmosphere, the suspension was heated to 90° C. and stirred overnight under a flow of N₂. After cooling to room temperature, water was added and the organic layer was separated. The solvent was evaporated under vacuum and the residue was used for the next step without further purification (yield: 95%). MS (ESI): 437.02 [M+H]⁺.

To a solution of N-([1,1′-biphenyl]-4-yl)-9,9-dimethyl-N-phenyl-9H-fluoren-2-amine (35.0 g, 80 mmol) in 150 mL DMF, N-bromosuccinimide (NBS) (16.02 g, 90 mmol) in 100 mL DMF was added dropwise in 30 min. After addition, the mixture was stirred at room temperature for 12 h and then poured into water to precipitate. The solid was filtrated and recrystallized from dichloromethane and ethanol to give white solid (yield: 92%). MS (ESI): 516.12 [M+H]⁺. ¹H-NMR (CDCl₃, 400 MHz, TMS, ppm): δ 7.65 (d, 2H), 7.59 (d, 2H), 7.50 (d, 2H), 7.40 (m, 8H), 7.17 (m, 3H), 7.05 (m, 3H), 1.42 (s, 6H). A mixture of N-([1,1′-biphenyl]-4-yl)-N-(4-bromophenyl)-9,9-dimethyl-9H-fluoren-2-amine (15.48 g, 30 mmol), 4,4,4′,4′,5,5,5′,5′-octamethyl-2,2′-bi(1,3,2-dioxaborolane) (9.14 g, 36 mmol), Pd(dppf)₂Cl₂ (571 mg, 0.75 mmol), CH₃COOK (4.41 g, 45 mmol), and 60 mL of dry dioxane were heated at 85° C. under nitrogen atmosphere for 12 h. After cooling to room temperature, solvent was removed under vacuum and then water was added. The mixture was extracted with CH₂Cl₂. The organic phase was collected and dried over anhydrous sodium sulphate. After filtration, the filtrate was evaporated to remove solvent and the residue was purified through column chromatography on silica gel to give white solid (84% yield). MS (ESI): 564.30 [M+H]⁺. ¹H-NMR (CDCl₃, 400 MHz, TMS, ppm): δ 7.65 (d, 2H), 7.59 (d, 2H), 7.50 (d, 2H), 7.40 (m, 8H), 7.17 (m, 3H), 7.05 (m, 3H), 1.42 (s, 6H), 1.38 (s, 12H).

### Synthesis of 6-bromo-9-(4-formylphenyl)-9H-carbazole-3-carbaldehyde (Compound 11)

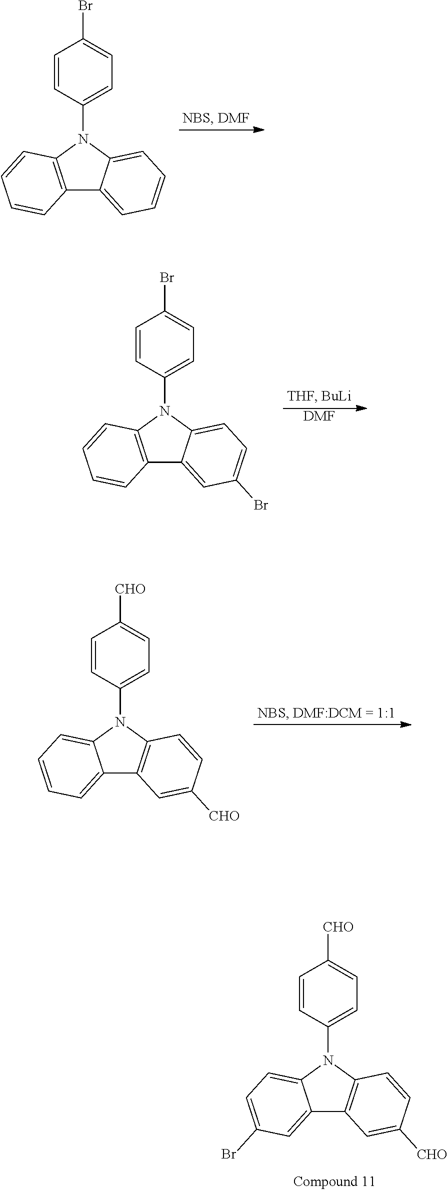

To a solution of 9-(4-bromophenyl)-9H-carbazole (32.2 g, 100 mmol) in 150 mL dimethyl formamide (DMF), N-bromosuccinimide (NBS) (17.8 g, 100 mmol) in 100 mL DMF was added dropwise in 30 min. After addition, the mixture was stirred at room temperature for 12 h and then poured into water to precipitate. The solid was filtrated and recrystallized from dichloromethane and ethanol to give white solid (92% yield) and used for the next step. The product had the following characteristic: MS (ESI): 402.09 [M+H]⁺.

To a solution of 3-bromo-9-(4-bromophenyl)-9H-carbazole (8.02 g, 20 mmol) in THF (500 mL), n-BuLi (24 mL of a 2.5M solution in hexanes, 60 mmol) was added at a rate to keep the internal temperature below −78° C. The mixture was stirred at −78° C. for 1 h and 10 mL DMF with 10 mL THF were added dropwise. After the addition, the reaction mixture was stirred at −45° C. for 30 min and at 0° C. for an additional 30 min Saturated aqueous NH₄Cl (400 mL) was added and the organic solvent was evaporated. The residue was extracted with CH₂Cl₂ (2×100 mL) and the combined organic phase was dried over anhydrous MgSO₄. After removing solvent, the crude product was purified through column chromatography to give crude product (65% yield). MS (ESI): 300.09 [M+H]⁺. ¹H-NMR (CDCl₃, 400 MHz, TMS, ppm): δ 10.15 (s, 1H), 10.13 (s, 1H), 8.67 (s, 1H), 8.23 (d, 1H), 8.17 (d, 2H), 7.99 (d, 1H), 7.80 (d, 2H), 7.54 (m, 3H), 7.40 (m, 1H).

To a solution of 9-(4-formylphenyl)-9H-carbazole-3-carbaldehyde (0.898 g, 3 mmol) in CH₂C₁₂ (20 mL) and DMF (20 mL), NBS (0.587 g, 3.3 mmol) was added in portion. After stirred for 4 h, the precipitates formed was filtered and washed with DMF and CH₂Cl₂ for several times to afford the crude product (84% yield). The product had the following characteristic: MS (ESI): 378.01 [M+H]⁺. (Fail to get ¹H-NMR data due to low solubility).

### Synthesis of 6-(4-([1,1′-biphenyl]-4-yl(9,9-dimethyl-9H-fluoren-2-yl)amino)phenyl)-9-(4-formylphenyl)-9H-carbazole-3-carbaldehyde (Compound 12)

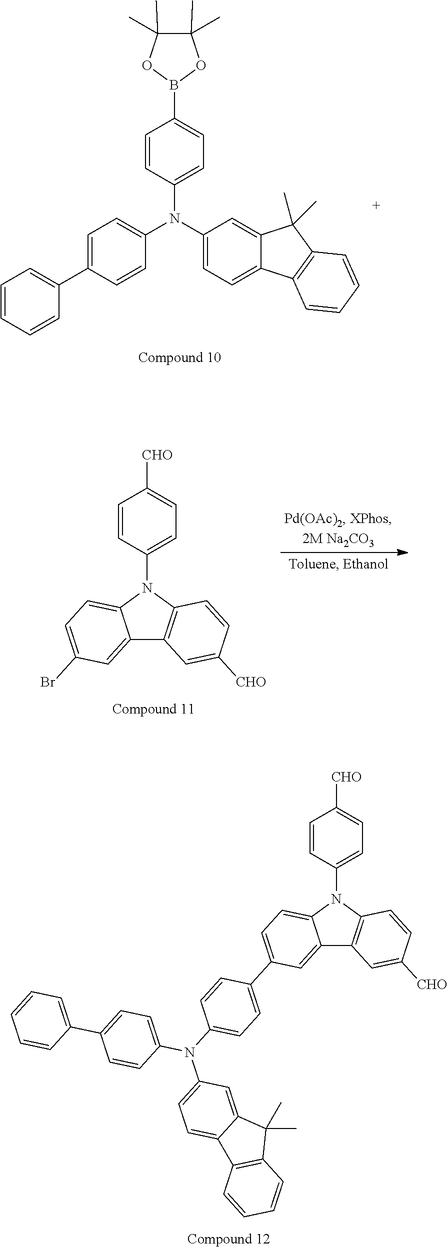 [SMILES: CC1(C)c2ccccc2-c2ccc(N(c3ccc(B4OC(C)(C)C(C)(C)O4)cc3)c3ccc(-c4ccccc4)cc3)cc21 ; O=Cc1ccc(-n2c3ccc(Br)cc3c3cc(C=O)ccc32)cc1 ; CC1(C)c2ccccc2-c2ccc(N(c3ccc(-c4ccccc4)cc3)c3ccc(-c4ccc5c(c4)c4cc(C=O)ccc4n5-c4ccc(C=O)cc4)cc3)cc21]

To a mixture of Compound 11 obtained above (0.756 g, 2 mmol), Compound 10 obtained above (1.24 g, 2.2 mmol), Pd(OAc)₂ (12.8 mg, 0.06 mmol) and X-Phos (28.6 mg, 0.06 mmol), 20 mL mixed solvents with proportion of 1:1:2 mixture of 2.0M Na₂CO₃:Ethanol:toluene were added under flow of nitrogen. The reaction mixture was stirred overnight under nitrogen atmosphere at 90° C. After evaporation of toluene and ethanol, water was added and the mixture was extracted with CH₂C₁₂ (2×30 mL) and the combined organic phase was dried over MgSO₄. The solvent was removed under reduced pressure and the residue was purified through column chromatography on silica gel to give yellow solid (64% yield). MS (ESI): 735.29 [M+H]+. ¹H-NMR (CDCl₃, 400 MHz, TMS, ppm): δ 10.12 (s, 1H), 10.09 (s, 1H), 8.36 (s, 1H), 8.20 (d, 1H), 7.64 (m, 12H), 7.53 (m, 2H), 7.42 (m, 6H), 7.32 (m, 7H), 7.15 (d, 1H), 4.88 (s, 2H), 4.85 (s, 2H), 1.45 (s, 6H).

### Synthesis of (4-(3-(4-([1,1′-biphenyl]-4-yl(9,9-dimethyl-9H-fluoren-2-yl)amino)phenyl)-6-(hydroxymethyl)-9H-carbazol-9-yl)phenyl)methanol (Compound 13)

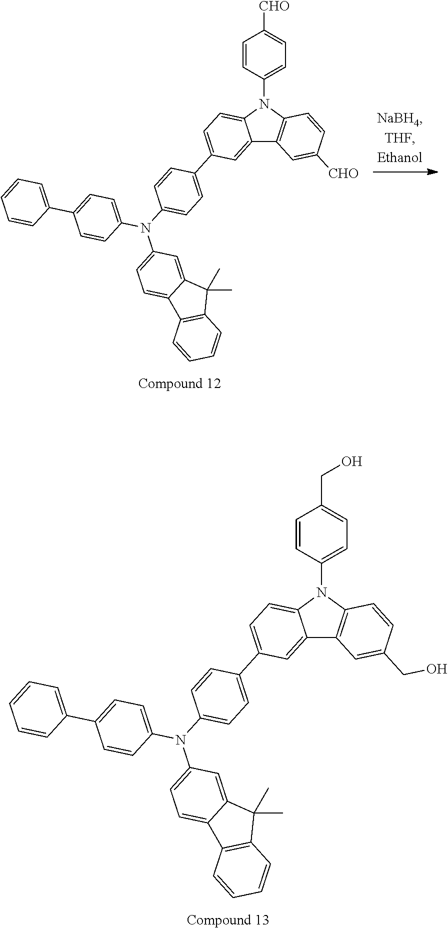 [SMILES: CC1(C)c2ccccc2-c2ccc(N(c3ccc(-c4ccccc4)cc3)c3ccc(-c4ccc5c(c4)c4cc(C=O)ccc4n5-c4ccc(C=O)cc4)cc3)cc21 ; CC1(C)c2ccccc2-c2ccc(N(c3ccc(-c4ccccc4)cc3)c3ccc(-c4ccc5c(c4)c4cc(CO)ccc4n5-c4ccc(CO)cc4)cc3)cc21]

To a solution of Compound 12 obtained above (734 mg, 1 mmol) in 10 mL THF and 10 mL ethanol at 40° C., NaBH₄ (302 mg, 8 mmol) was added under nitrogen atmosphere. The solution was allowed to stir at room temperature for 2 h. Then, aqueous hydrochloric acid solution was added until pH 5 and the mixture was kept stirring for 30 min. The solvent was removed under vacuum and the residue was extracted with dichloromethane. The product was then dried under vacuum and used for the next step without further purification (95% yield). MS (ESI): 739.32 [M+H]⁺. ¹H-NMR (CDCl₃, 400 MHz, TMS, ppm): δ 8.36 (s, 1H), 8.20 (d, 1H), 7.64 (m, 12H), 7.53 (m, 2H), 7.42 (m, 6H), 7.32 (m, 7H), 7.15 (d, 1H), 4.88 (s, 2H), 4.85 (s, 2H), 3.74 (m, 2H), 1.45 (s, 6H).

### Synthesis of Monomer B4: N-([1,1′-biphenyl]-4-yl)-9,9-dimethyl-N-(4-(6-(((4-vinylbenzyl)oxy)methyl)-9-(4-(((4-vinylbenzyl)oxy)methyl)phenyl)-9H-carbazol-3-yl)phenyl)-9H-fluoren-2-amine (Monomer B4, 99.8% Purity)

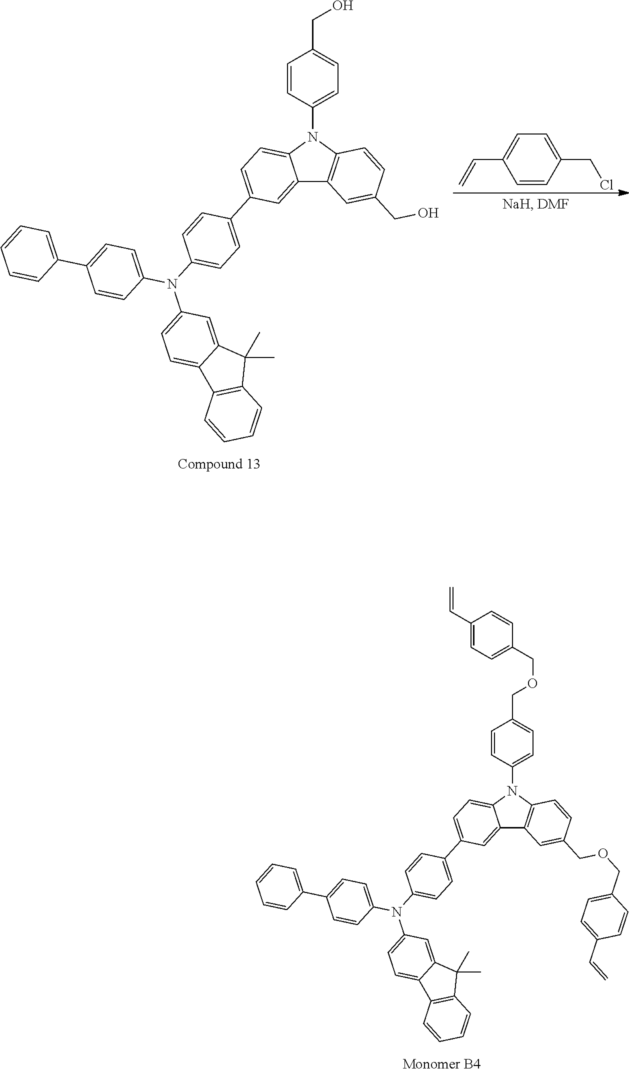

To a solution of Compound 13 obtained above (3.69 g, 5 mmol) in 50 mL dry DMF was added NaH (432 mg, 18 mmol), the mixture was stirred at room temperature for 1 h. And 1-(chloromethyl)-4-vinylbenzene (2.75 g, 15 mmol) was added to above solution via syringe. The mixture was heated to 60° C. overnight. After quenched with water, the mixture was poured into water to remove DMF. The residue was filtrated and the resulting solid was dissolved with dichloromethane, which was then washed with water. The solvent was removed under vacuum and the residue was extracted with dichloromethane. The product was then obtained by column chromatography on silica gel (55% yield). MS (ESI): 943.42 [M+H]⁺. ¹H-NMR (CDCl₃, 400 MHz, TMS, ppm): δ 8.35 (s, 1H), 8.17 (d, 1H), 7.62 (m, 12H), 7.42 (m, 14H), 7.29 (m, 10H), 6.72 (dd, 2H), 5.77 (d, 2H), 5.24 (d, 2H), 4.74 (s, 2H), 4.67 (s, 4H), 4.60 (s, 2H), 1.45 (s, 6H).

### Example (Ex) 1 and Comparative (Comp) Exs A and B OLED Fabrication

Glass substrates (20 mm by 20 mm) having a “3 mm by 3 mm” Indium Tin Oxide (ITO) area were cleaned with solvents (ethanol, acetone, isopropanol sequentially) and ultraviolet/ozone (UVO) Treatment. The ITO layer is 150 nm thick.

Each cell containing HIL, HTL, EML, ETL and EIL, was prepared based on materials listed in Table 1.

For the hole injection layer, Plexcore™ OC RG-1200 (Poly(thiophene-3-[2-(2-methoxyethoxy)ethoxy]-2,5-diyl) available from Sigma-Aldrich, a sulfonated solution filtered with 0.5 micro polytetrafluoroethylene (PTFE) syringe filter) was spin-coated (speed: 5s 1000 rpm, 30s 5000 rpm), inside a nitrogen filled glove-box, onto the ITO Glass substrates. The spin-coated film was annealed at 150° C. for 20 minutes. The annealed film thickness was in the range of 30-80 nm.

The HTL material solution in anisole (22 mg/mL, filtered with 0.5 micro polytetrafluoroethylene (PTFE) syringe filter) was spin-coated (speed: 5s 2000 rpm, 30s 4000 rpm), onto the HIL coated ITO Glass substrates and annealed (annealing conditions are given in Table 2). The annealed film thickness was in the range of 10-200 nm.

These substrates were then transferred into a thermal evaporator, under a vacuum of approximately 1*10⁻⁷ Torr. For the emitting material layer, 9-(4,6-diphenylpyrimidin-2-yl)-9′-phenyl-9H,9′H-3,3′-bicarbazole (host) and tris[3-[4-(1,1-dimethylethyl)-2-pyridinyl-κN][1,1′-biphenyl]-4-yl-κC]iridium (dopant) were co-evaporated, until the thickness reached 400 Angstrom. The deposition rate for host material was 0.85 A/s, and the deposition for the dopant material was 0.15 A/s, resulting in a 15% by weight doping of the host material EML. For the electron transport layer, 2,4-bis(9,9-dimethyl-9H-fluoren-2-yl)-6-(naphthalen-2-yl)-1,3,5-triazine was co-evaporated with lithium quinolate(Liq), until the thickness reached 350 Angstrom. The evaporation rate for the ETL compounds and Liq was 0.4 A/s and 0.6 A/s. Finally, “20 Angstrom” of a thin electron injection layer (Liq) was evaporated at a 0.5 A/s rate. Finally, these OLED (reported in Table 1) were hermetically sealed prior to testing. The OLED have the following common structure:

### HIL (400 Å±20 Å)/HTL (200˜300 Å)/Green EML(400 Å)/ETL:Liq(350 Å)/Liq(20 Å).

TABLE 1

| | Name | CAS No. |
|---|---|---|
| HIL | Poly(thiophene-3-[2-(2-methoxyethoxy)eth- | 1003582-37-3 |
| compound | oxy]-2,5-diyl), sulfonated solution | |
| HTL | Comp Ex B: N4,N4′-di(naphthalen-1-yl)- | 123847-85-8 |
| compound | N4,N4′-diphenyl-[1,1′-biphenyl]-4,4′- | |
| | diamine | |
| | Com Ex A: Monomer B1 | |
| | Ex 1: Monomer B1: 10% dopant | |
| Green | 9-(4,6-diphenylpyrimidin-2-yl)-9′-phenyl- | 1266389-00-7 |
| Host | 9H,9′H-3,3′-bicarbazole | |
| Green | Iridium, tris[3-[4-(1,1-dimethyl-ethyl)- | 1528724-69-7 |
| Dopant | 2-pyridinyl-κN] [1,1′-biphenyl]-4-yl- | |
| | κC]- | |
| ETL | 2,4-bis(9,9-dimethyl-9H-fluoren-2-yl)- | 1459162-51-6 |
| compound | 6-(naphthalen-2-yl)-1,3,5-triazine | |
| EIL | lithium quinolate | 850918-68-2 |
| compound | | |

TABLE 2

| | | Annealing conditions for |
|---|---|---|
| Example | HTL material | preparing HTL |
| Comp Ex A | Monomer B1 | 280° C., 60 min |
| Ex 1 | Monomer B1: | 280° C., 60 min |
| | 10%* p-dopant | |
| Comp Ex B | NPB | 150° C., 20 min |

*by weight based on the total weight of Monomer B1 and p-dopant

The current-voltage-brightness (J-V-L) characterizations for the OLED were performed with a source measurement unit (KEITHLY 238) Luminescence meter (MINOLTA CS-100A). EL spectra of the OLED devices were collected by a calibrated CCD spectrograph.

As shown in Table 3, the device of Ex 1 showed significantly lower driving voltage and comparable efficiency as compared to that of Comp Ex A using Monomer B1 as hole transport layer, and significantly higher efficiency compared to that of Comp Ex B comprising NPB as the hole transport layer.

TABLE 3

| | | Turn-on | | |
|---|---|---|---|---|
| | | Voltage | Efficiency | CIE |
| | HTL material | (V) | (Cd/A) | (x, y) |
| Comp Ex A | Monomer B1 | 4.8 | 60 | 0.300, 0.646 |
| Ex 1 | Monomer B1: | 3.4 | 58 | 0.296, 0.649 |
| | 10% dopant | | | |
| Comp Ex B | NPB | 3.7 | 34 | 0.303, 0.651 |

What is claimed is:

1. A polymeric layer formed by a composition comprising,
(a) from 1% to 20% by weight of a p-dopant, based on the total weight of the composition, wherein the p-dopant is selected from trityl salts, ammonium salts, iodonium salts, tropylium salts, imidazolium salts, phosphonium salts, oxonium salts, or mixtures thereof; and
(b) one or more monomers comprising, based on the total moles of the monomers in the composition, from 54% to 100% by mole of Monomer B; wherein Monomer B has the structure represented by Structure B: 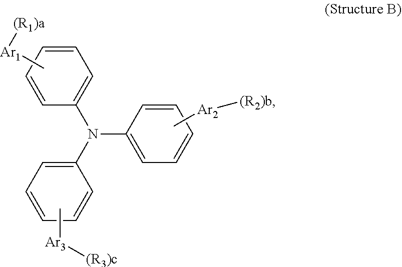
Ar₁, Ar₂ and Ar₃ are each independently selected from a C₆-C₆₀ substituted arylene, a C₆-C₆₀ arylene, a C₄-C₆₀ substituted heteroarylene, or a C₄-C₆₀ heteroarylene; Ar₁, Ar₂ and Ar₃ may each independently form a ring structure with the adjacent phenyl group they are bonded to;
(R₁)ₐ, (R₂)_{b} and (R₃)_{c} are each independently selected from hydrogen, a C₁-C₆₀ hydrocarbyl, a C₁-C₆₀ substituted hydrocarbyl, a halogen, a cyano, a nitro, a C₁-C₆₀ alkoxy, or a hydroxyl; with the proviso that two or more of (R₁)ₐ, (R₂)_{b} and (R₃)_{c} independently have the following Structure D: 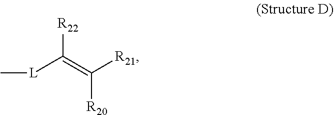
wherein L is selected from a covalent bond, a heteroatom, an aromatic moiety, a heteroaromatic moiety, a C₁-C₁₀₀ hydrocarbyl, a C₁-C₁₀₀ substituted hydrocarbyl, a C₁-C₁₀₀ heterohydrocarbyl, or a C₁-C₁₀₀ substituted heterohydrocarbyl; and
wherein R₂₀ through R₂₂ are each independently selected from hydrogen, deuterium, a C₁-C₅₀ hydrocarbyl, a C₁-C₅₀ substituted hydrocarbyl, a C₁-C₅₀ heterohydrocarbyl, a C₁-C₅₀ substituted heterohydrocarbyl, a halogen, a cyano, a C₆-C₅₀ aryl, a C₆-C₅₀ substituted aryl, a C₄-C₅₀ heteroaryl, or a C₄-C₅₀ substituted heteroaryl.

2. The polymeric layer of claim 1, wherein Monomer B has the structure represented by Structure B-I: 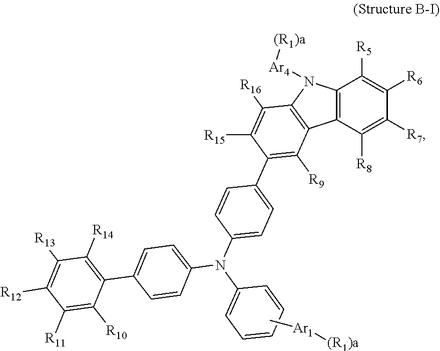
wherein Ar₁ and Ar₄ are each independently selected from a C₆-C₆₀ substituted arylene, a C₆-C₆₀ arylene, a C₄-C₆₀ substituted heteroarylene, or a C₄-C₆₀ heteroarylene;
R₅ through R₁₆ are each independently selected from hydrogen, a C₁-C₆₀ hydrocarbyl, a C₁-C₆₀ substituted hydrocarbyl, a halogen, a cyano, a nitro, a C₁-C₆₀ alkoxy, or a hydroxyl;
wherein at least one of R₁₀ through R₁₄ is (R₂)_{b};
wherein (R₁)ₐ, (R₂)_{b} and (R₄)_{d} are each independently selected from hydrogen, a C₁-C₆₀ hydrocarbyl, a C₁-C₆₀ substituted hydrocarbyl, a halogen, a cyano, a nitro, a C₁-C₆₀ alkoxy, or a hydroxyl; with the proviso that two or more of (R₁)ₐ, (R₂)_{b}, (R₄)_{d} and R₅ through R₁₆ have the structure represented by Structure D.

3. The polymeric layer of claim 2, wherein Ar₁ and Ar₄ in Structure B-I are each independently selected from the following structure:

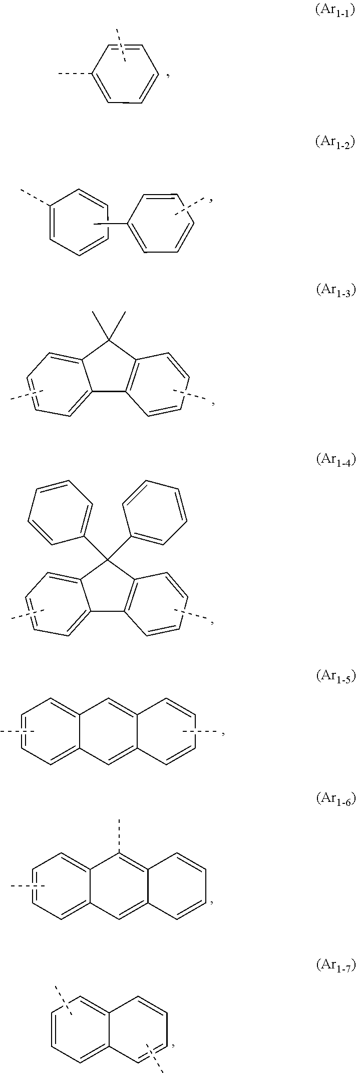

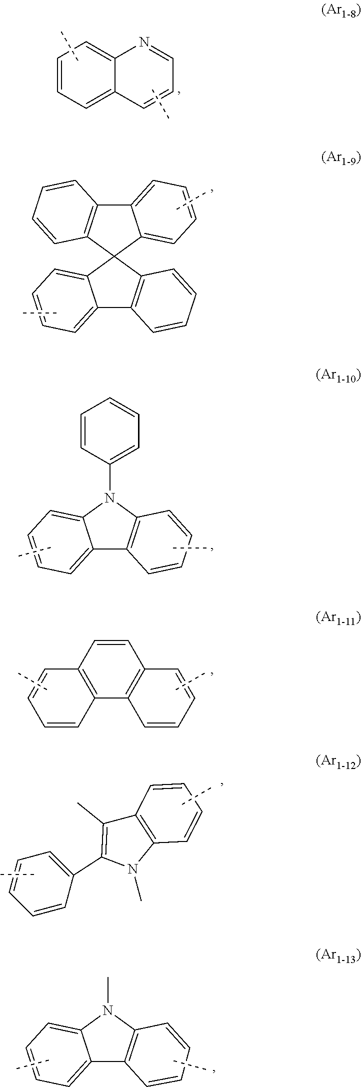

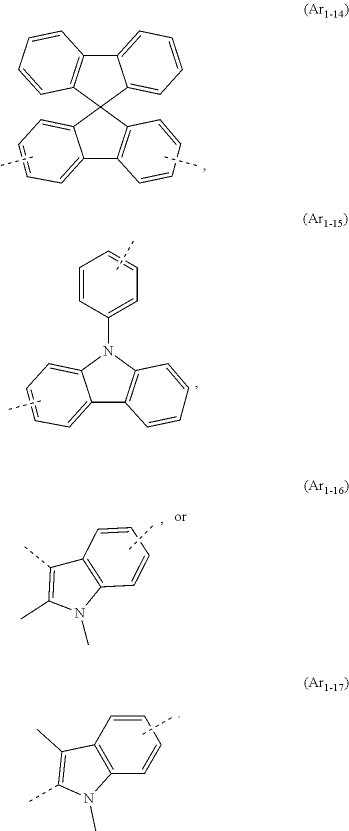

4. The polymeric layer of claim 1, wherein Ar₁, Ar₂ and Ar₃ in Structure B are each independently selected from the following structure:

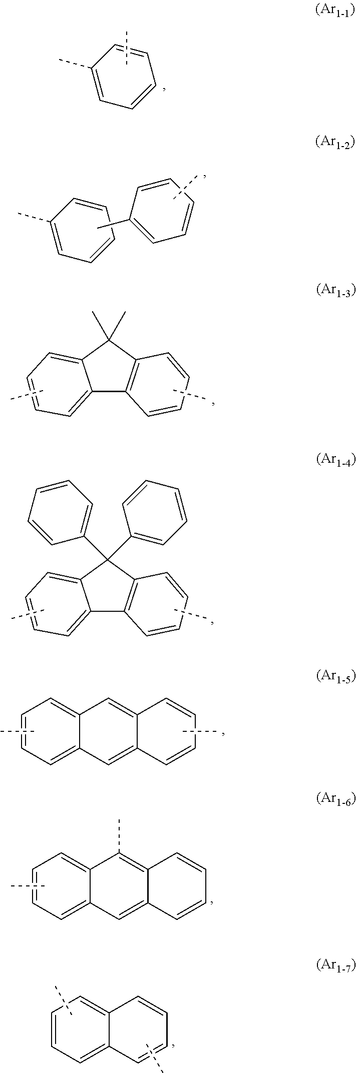

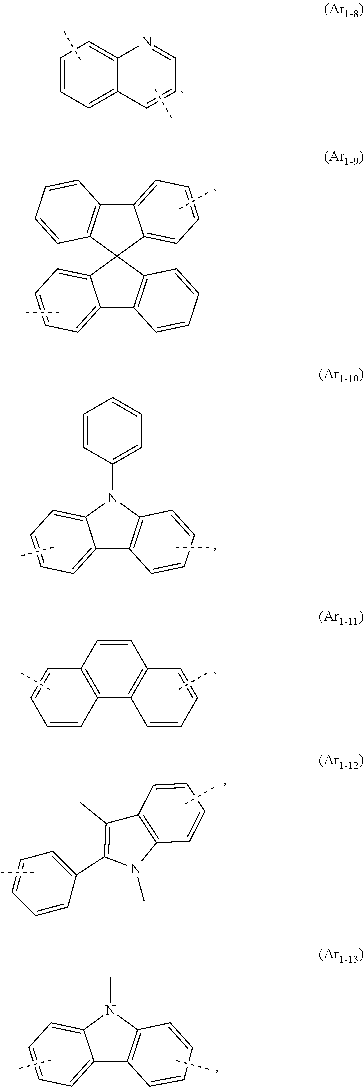

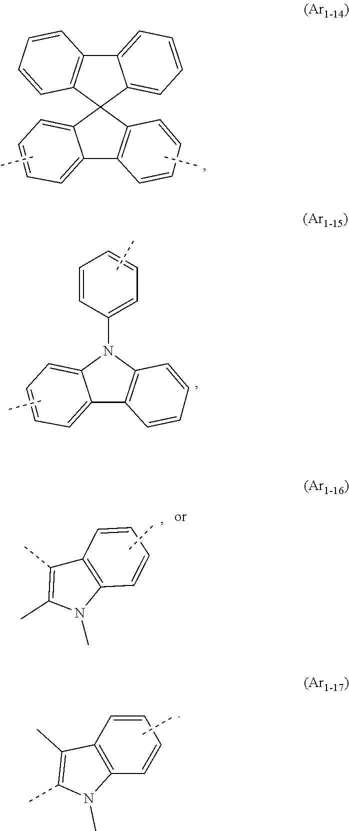

5. The polymeric layer of claim 1, wherein Monomer B has the following Structure B-II: 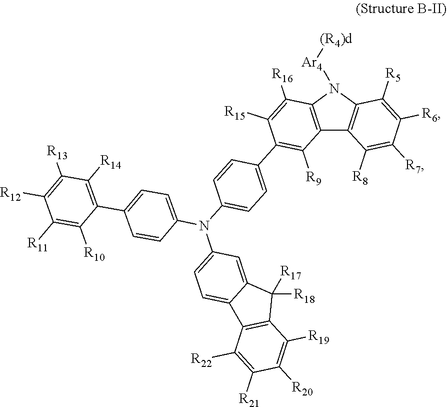
wherein R₅ through R₂₂ are each independently selected from hydrogen, a C₁-C₆₀ hydrocarbyl, a C₁-C₆₀ substituted hydrocarbyl, a halogen, a cyano, a nitro, a C₁-C₆₀ alkoxy, or a hydroxyl;
wherein one of R₁₇ through R₂₂ is (R₁)ₐ;
wherein one of R₁₀ through R₁₄ is (R₂)_{b};
wherein (R₁)ₐ, (R₂)_{b} and (R₄)_{d} are each independently selected from hydrogen, a C₁-C₆₀ hydrocarbyl, a C₁-C₆₀ substituted hydrocarbyl, a halogen, a cyano, a nitro, a C₁-C₆₀ alkoxy, or a hydroxyl; with the proviso that two or more of (R₁)ₐ, (R₂)_{b}, (R₄)_{d} and R₅ through R₂₂ have the structure represented by Structure D;
wherein Ar₄ is selected from a C₆-C₆₀ substituted arylene, a C₆-C₆₀ arylene, a C₄-C₆₀ substituted heteroarylene, or a C₄-C₆₀ heteroarylene; and
wherein one or more hydrogen atoms may be optionally substituted with deuterium.

6. The polymeric layer of claim 1, wherein Monomer B has the following Structure B-III: 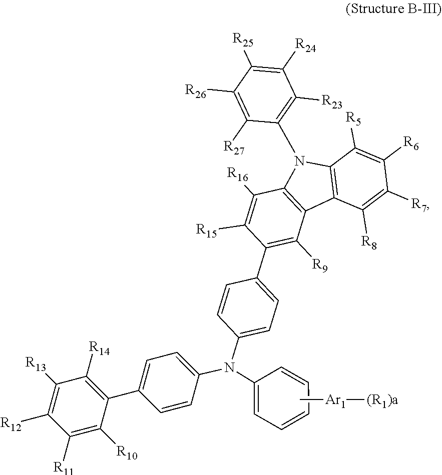
wherein R₅ through R₁₆ and R₂₃ through R₂₇ are each independently selected from hydrogen, a C₁-C₆₀ hydrocarbyl, a C₁-C₆₀ substituted hydrocarbyl, a halogen, a cyano, a nitro, a C₁-C₆₀ alkoxy, or a hydroxyl;
wherein one of R₁₀ through R₁₄ is (R₂)_{b};
wherein one of R₂₃ through R₂₇ is (R₄)_{d},
wherein (R₁)ₐ, (R₂)_{b} and (R₄)_{d} are each independently selected from hydrogen, a C₁-C₆₀ hydrocarbyl, a C₁-C₆₀ substituted hydrocarbyl, a halogen, a cyano, a nitro, a C₁-C₆₀ alkoxy, or a hydroxyl; with the proviso that two or more of groups (R₁)ₐ, (R₂)_{b}, (R₄)_{d}, R₅ through R₁₆, and R₂₃ through R₂₇ have the structure represented by Structure D;
wherein Ar₁ is selected from a C₆-C₆₀ substituted arylene, a C₆-C₆₀ arylene, a C₄-C₆₀ substituted heteroarylene, or a C₄-C₆₀ heteroarylene; and
wherein one or more hydrogen atoms may be optionally substituted with deuterium.

7. The polymeric layer of claim 1, wherein L in Structure D is selected from -alkylene-, -arylene-, -alkylene-arylene-, -arylene-alkylene-, or a covalent bond.

8. The polymeric layer of claim 1, wherein Structure D is selected from D-1 through D-12:

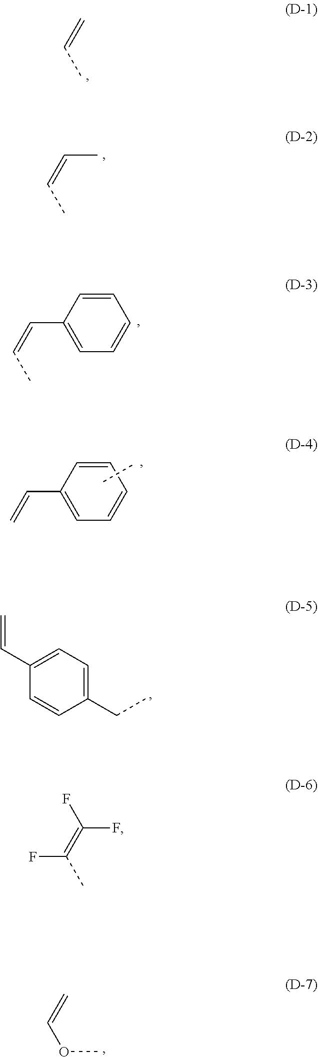

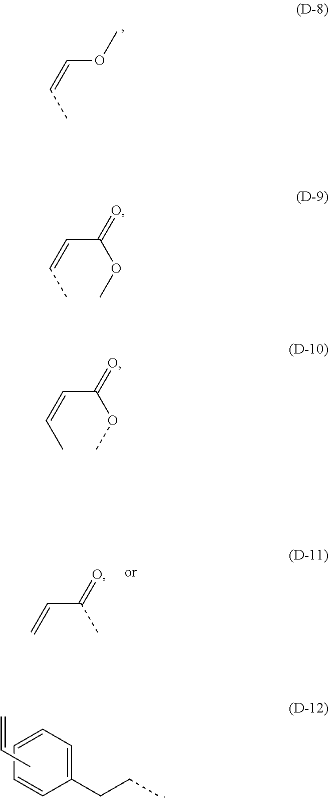

9. The polymeric layer of claim 1, wherein Monomer B is selected from the following compounds (B1) through (B16):

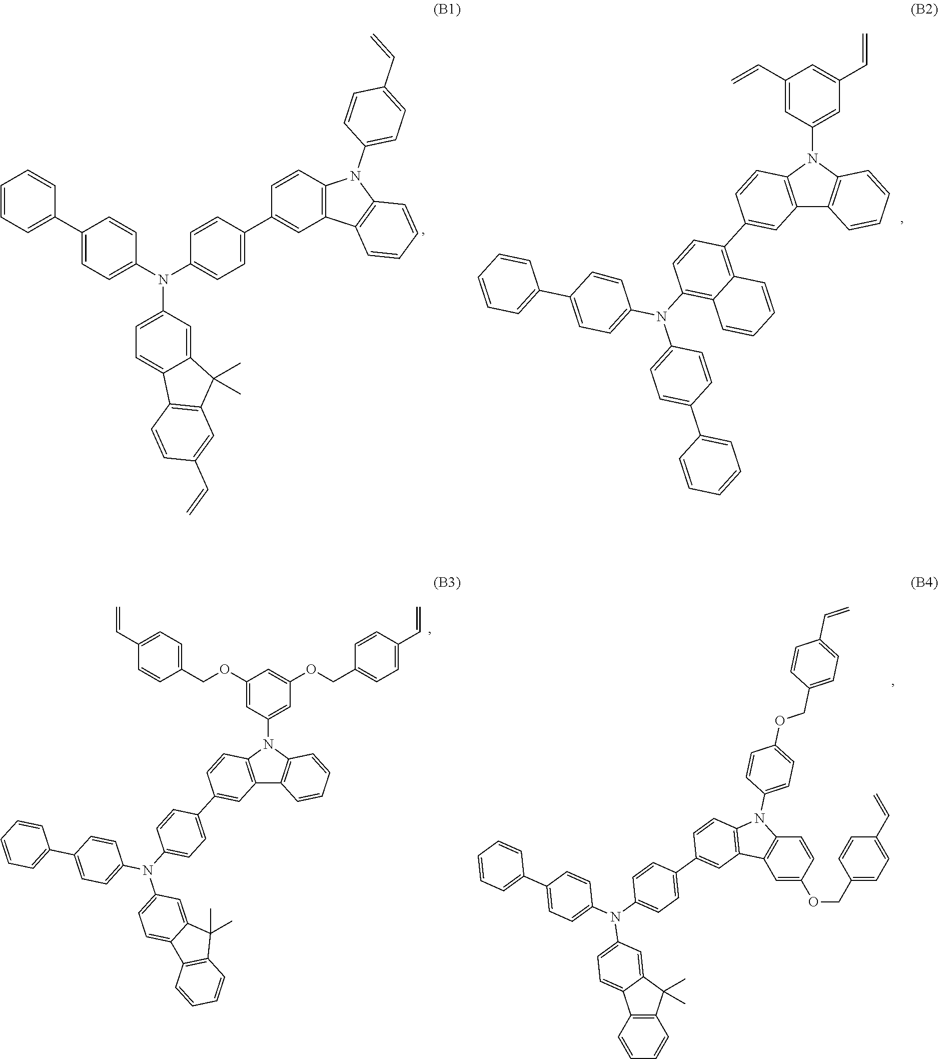 [SMILES: C=Cc1ccc(-n2c3ccccc3c3cc(-c4ccc(N(c5ccc(-c6ccccc6)cc5)c5ccc6c(c5)C(C)(C)c5cc(C=C)ccc5-6)cc4)ccc32)cc1 ; C=Cc1cc(C=C)cc(-n2c3ccccc3c3cc(-c4ccc(N(c5ccc(-c6ccccc6)cc5)c5ccc(-c6ccccc6)cc5)c5ccccc45)ccc32)c1 ; C=Cc1ccc(COc2cc(OCc3ccc(C=C)cc3)cc(-n3c4ccccc4c4cc(-c5ccc(N(c6ccc(-c7ccccc7)cc6)c6ccc7c(c6)C(C)(C)c6ccccc6-7)cc5)ccc43)c2)cc1 ; C=Cc1ccc(COc2ccc(-n3c4ccc(OCc5ccc(C=C)cc5)cc4c4cc(-c5ccc(N(c6ccc(-c7ccccc7)cc6)c6ccc7c(c6)C(C)(C)c6ccccc6-7)cc5)ccc43)cc2)cc1]

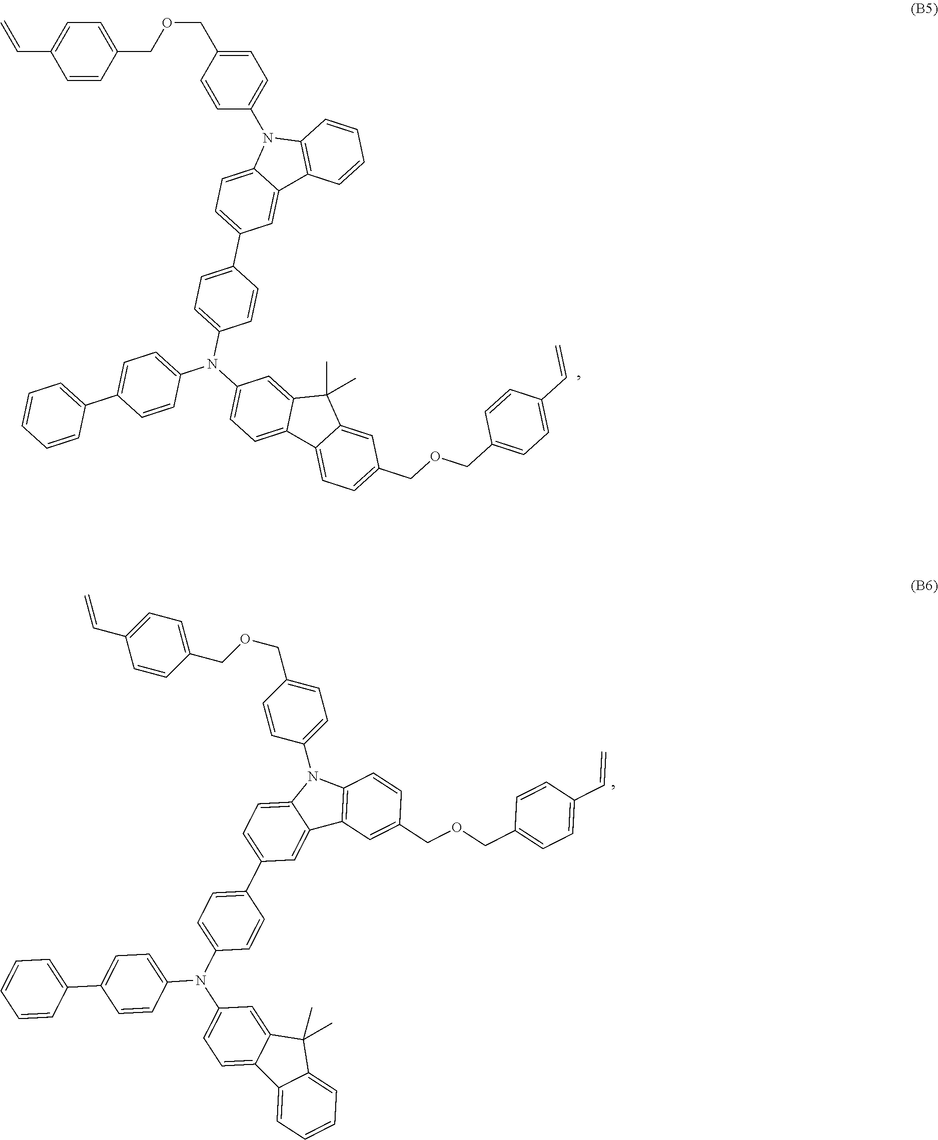 [SMILES: C=Cc1ccc(COCc2ccc(-n3c4ccccc4c4cc(-c5ccc(N(c6ccc(-c7ccccc7)cc6)c6ccc7c(c6)C(C)(C)c6cc(COCc8ccc(C=C)cc8)ccc6-7)cc5)ccc43)cc2)cc1 ; C=Cc1ccc(COCc2ccc(-n3c4ccc(COCc5ccc(C=C)cc5)cc4c4cc(-c5ccc(N(c6ccc(-c7ccccc7)cc6)c6ccc7c(c6)C(C)(C)c6ccccc6-7)cc5)ccc43)cc2)cc1]

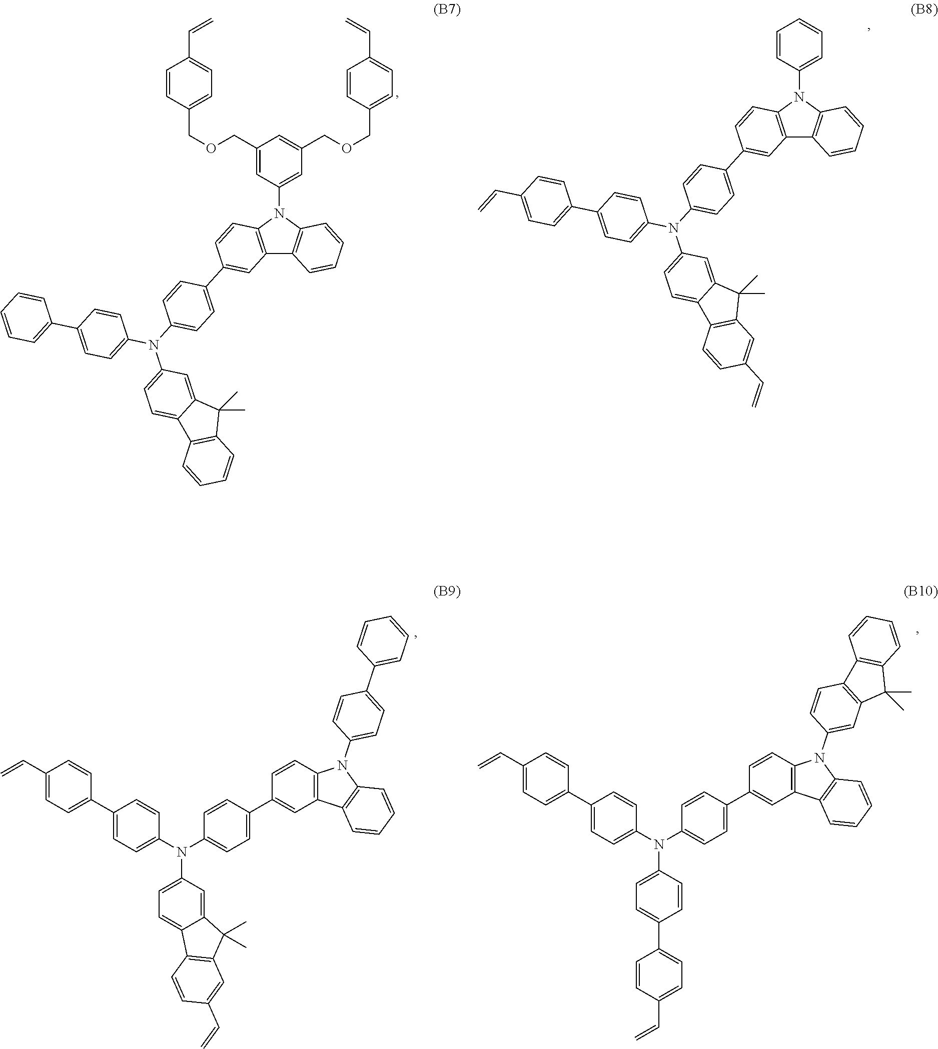 [SMILES: C=Cc1ccc(COCc2cc(COCc3ccc(C=C)cc3)cc(-n3c4ccccc4c4cc(-c5ccc(N(c6ccc(-c7ccccc7)cc6)c6ccc7c(c6)C(C)(C)c6ccccc6-7)cc5)ccc43)c2)cc1 ; C=Cc1ccc(-c2ccc(N(c3ccc(-c4ccc5c(c4)c4ccccc4n5-c4ccccc4)cc3)c3ccc4c(c3)C(C)(C)c3cc(C=C)ccc3-4)cc2)cc1 ; C=Cc1ccc(-c2ccc(N(c3ccc(-c4ccc5c(c4)c4ccccc4n5-c4ccc(-c5ccccc5)cc4)cc3)c3ccc4c(c3)C(C)(C)c3cc(C=C)ccc3-4)cc2)cc1 ; C=Cc1ccc(-c2ccc(N(c3ccc(-c4ccc(C=C)cc4)cc3)c3ccc(-c4ccc5c(c4)c4ccccc4n5-c4ccc5c(c4)C(C)(C)c4ccccc4-5)cc3)cc2)cc1]

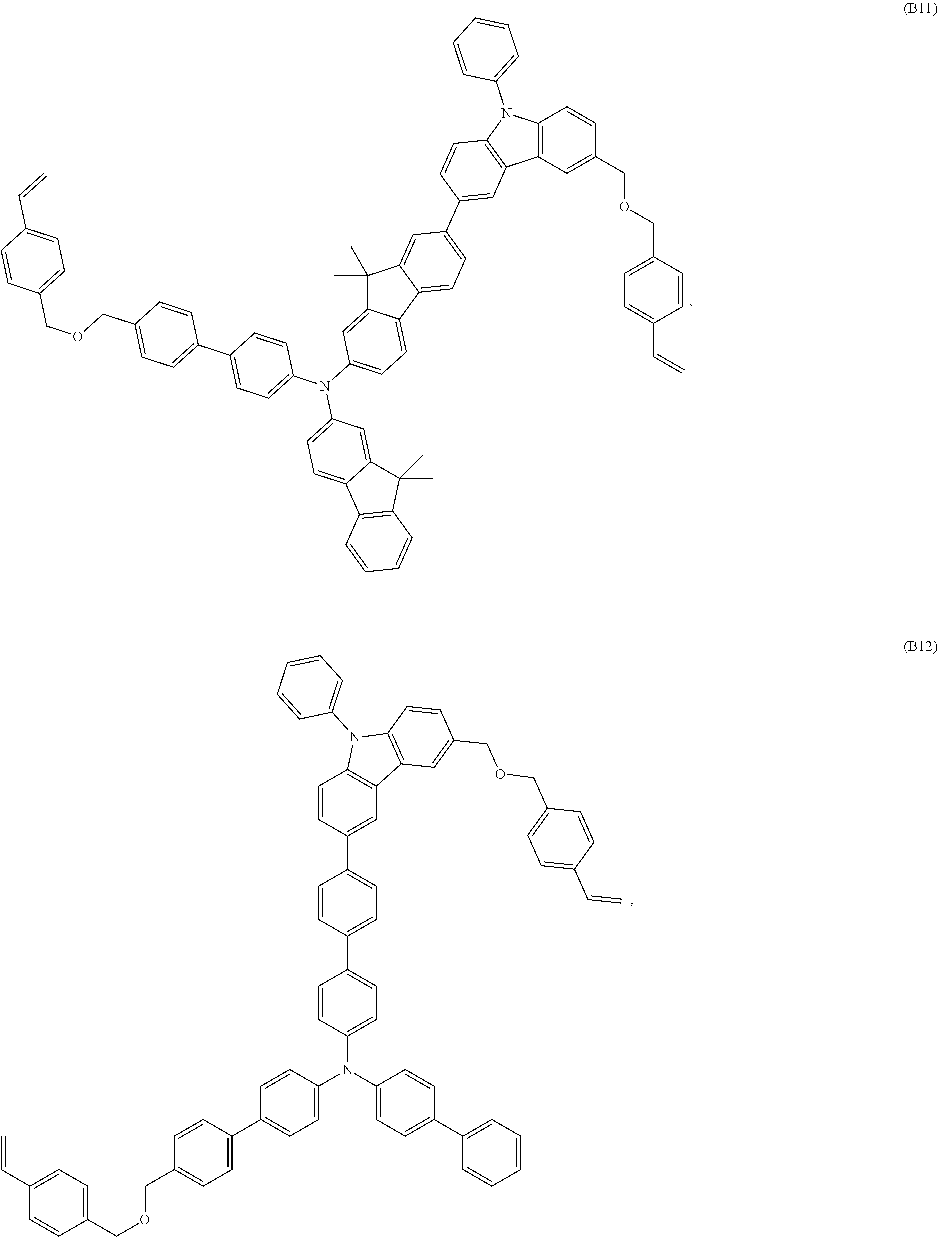

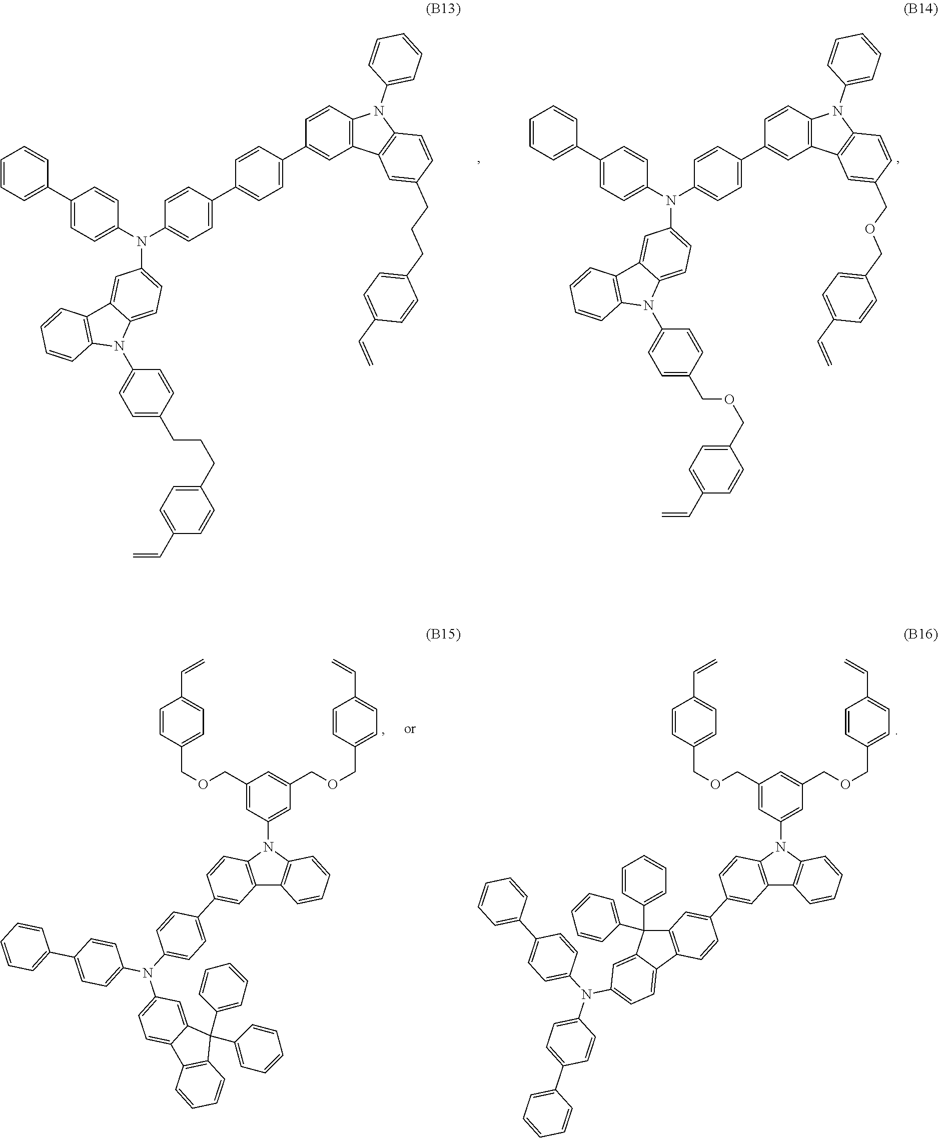

10. The polymeric layer of claim 1, wherein the p-dopant has a structure selected from (p-1) through (p-13):

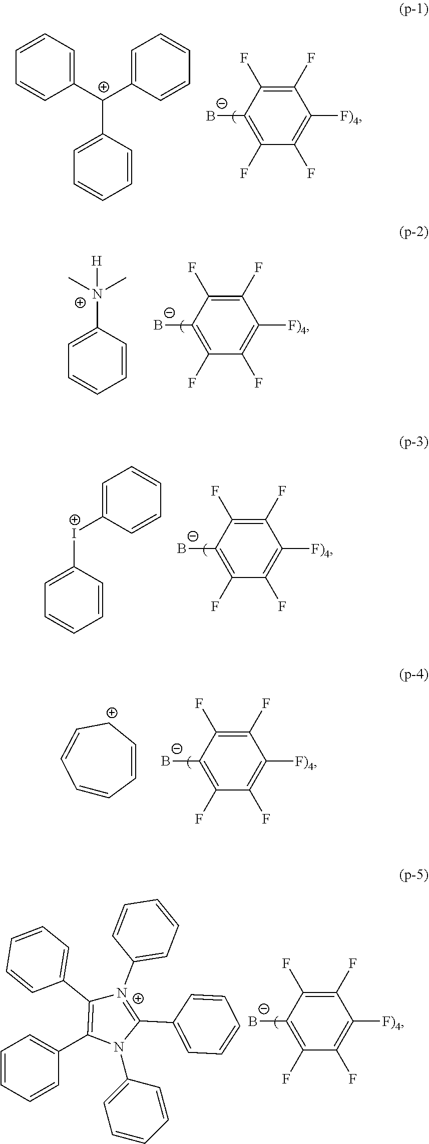

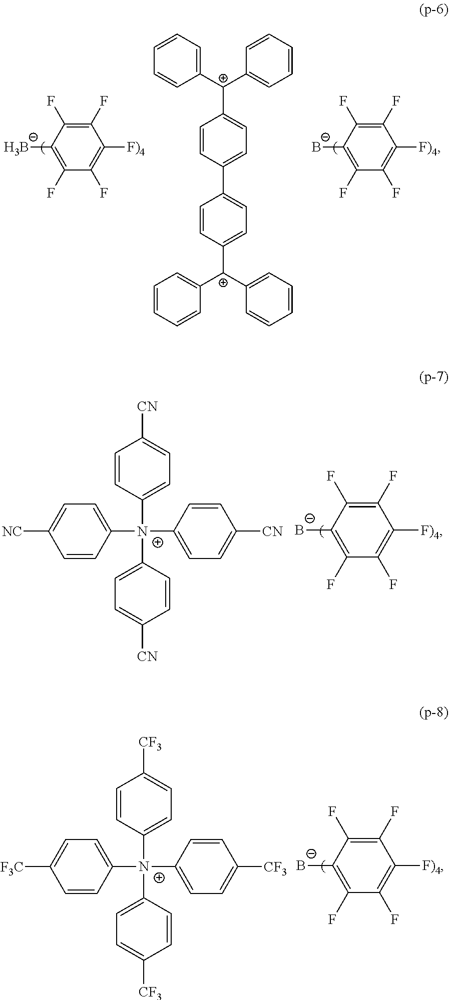

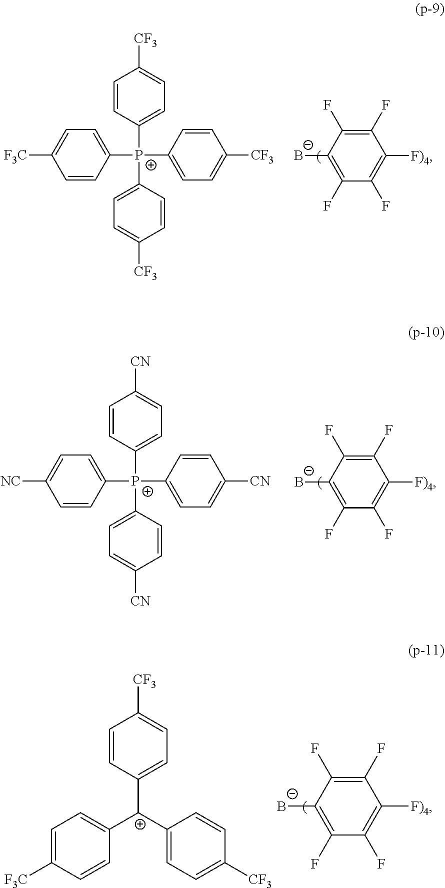

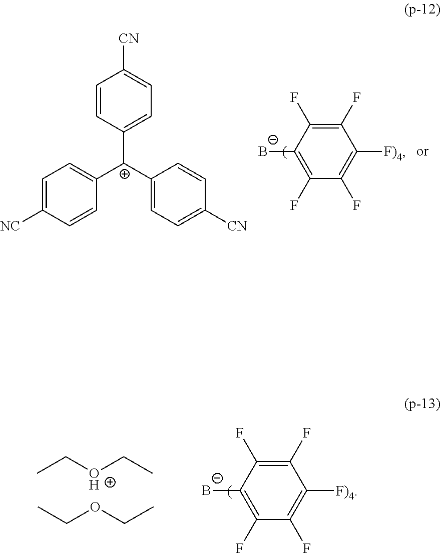

11. The polymeric layer of claim 1, wherein Monomer B has a molecular weight of from 500 g/mole to 28,000 g/mole.

12. The polymeric layer of claim 1, wherein Monomer B has a purity equal to or above 99%.

13. A method of making a polymeric layer, comprising:
(i) providing a composition comprising,
(a) from 1% to 20% by weight of a p-dopant, based on the total weight of the composition, wherein the p-dopant is selected from trityl salts, ammonium salts, iodonium salts, tropylium salts, imidazolium salts, phosphonium salts, oxonium salts, or mixtures thereof; and
(b) one or more monomers comprising, based on the total moles of the monomers in the composition, from 54% to 100% by mole of Monomer B; wherein Monomer B has the structure represented by Structure B: 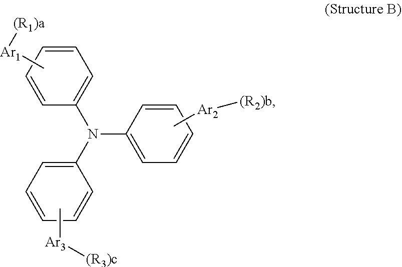
Ar₁, Ar₂ and Ar₃ are each independently selected from a C₆-C₆₀ substituted arylene, a C₆-C₆₀ arylene, a C₄-C₆₀ substituted heteroarylene, or a C₄-C₆₀ heteroarylene; Ar₁, Ar₂ and Ar₃ may each independently form a ring structure with the adjacent phenyl group they are bonded to;
(R₁)ₐ, (R₂)_{b} and (R₃)_{c} are each independently selected from hydrogen, a C₁-C₆₀ hydrocarbyl, a C₁-C₆₀ substituted hydrocarbyl, a halogen, a cyano, a nitro, a C₁-C₆₀ alkoxy, or a hydroxyl; with the proviso that two or more of (R₁)ₐ, (R₂)_{b} and (R₃)_{c} independently have the following Structure D: 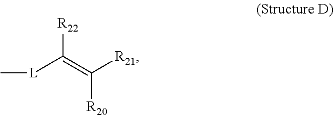
wherein L is selected from a covalent bond, a heteroatom, an aromatic moiety, a heteroaromatic moiety, a C₁-C₁₀₀ hydrocarbyl, a C₁-C₁₀₀ substituted hydrocarbyl, a C₁-C₁₀₀ heterohydrocarbyl, or a C₁-C₁₀₀ substituted heterohydrocarbyl; and
wherein R₂₀ through R₂₂ are each independently selected from hydrogen, deuterium, a C₁-C₅₀ hydrocarbyl, a C₁-C₅₀ substituted hydrocarbyl, a C₁-C₅₀ heterohydrocarbyl, a C₁-C₅₀ substituted heterohydrocarbyl, a halogen, a cyano, a C₆-C₅₀ aryl, a C₆-C₅₀ substituted aryl, a C₄-C₅₀ heteroaryl, or a C₄-C₅₀ substituted heteroaryl;
(ii) dissolving or dispersing the composition in one or more organic solvents to obtain a crosslinkable solution;
(iii) depositing the crosslinkable solution to a substrate; and
(iv) crosslinking and drying the crosslinkable solution to form the polymeric layer.

14. An organic electronic device comprising a polymeric layer of claim 1.

15. The organic device of claim 14, wherein the electronic device is a light emitting device.
